(19) United States
(12) Patent Application Publication
(10) Pub. No.: US 2026/0114090 A1
(43) Pub. Date: Apr. 23, 2026

(54) OXIDE PHOSPHOR AND LIGHT EMITTING DEVICE

(71) Applicant: NICHIA CORPORATION, Anan-shi (JP)

(72) Inventor: Yoshinori MURAZAKI, Komatsushima-shi (JP)

(73) Assignee: NICHIA CORPORATION, Anan-shi (JP)

(21) Appl. No.: 19/360,961

(22) Filed: Oct. 16, 2025

(30) Foreign Application Priority Data
Oct. 18, 2024 (JP) 2024-182934

(51) Int. Cl. H10H 20/851; C09K 11/68

(52) U.S. Cl. CPC H10H 20/8512; C09K 11/68; C09K 11/685

(57) ABSTRACT

An oxide phosphor has a composition represented by the following formula (1).

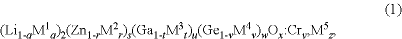

wherein M¹ represents one or more selected from Na, K, Rb, and Cs, M² represents one or more selected from Mg, Ca, Sr, and Ba, M³ represents one or more selected from Al, Sc, and In, M⁴ represents one or more selected from Si, Ti, Zr, Sn, and Hf, M⁵ represents one or more selected from Ni, Ce, Eu, Fe, Mn, Nd, Tm, Ho, Er, and Yb, 0≤q≤0.5, 0≤r≤1.0 0≤s≤4.0, 0≤t≤1.0, 5≤u≤10, 0≤v≤1.0, 0.5≤w≤5.0, 10≤x≤30, and y and z satisfy 0.02≤y≤0.5, 0≤z≤0.3, and y>z.

### CROSS-REFERENCE TO RELATED PATENT APPLICATION

This application claims priority to Japanese Patent Application No. 2024-182934, filed on Oct. 18, 2024, the disclosure of which is hereby incorporated by reference in its entirety.

### BACKGROUND

The present disclosure relates to an oxide phosphor and a light emitting device.

### TECHNICAL FIELD

Light emitting devices having light emission intensity in a wavelength range from red light to near-infrared light are desired for use in applications such as light sources for plant growth and cultivation. In addition to the applications described above, light emitting devices having light emission intensity in a wavelength range from red light to near-infrared light are desired for use in applications such as infrared cameras, infrared communications, vein authentication, which is a type of biometric authentication, and food component analyzers for non-destructive measurement of sugar content in foods such as fruits and vegetables. Light emitting devices that emit light in the wavelength range from red light to near-infrared light as well as in a wavelength range of visible light are also desired.

Examples of such light emitting devices include a light emitting device in which a light emitting diode (LED) and a phosphor are combined.

As the phosphor that can also be used in the light emitting devices described above, Japanese Translation of PCT International Application Publication No. 2020-528486 discloses a phosphor having a light emission peak wavelength in a range of 680 nm or more and 760 nm or less and having a composition represented by CaYAlO₄:Mn⁴⁺. As the phosphor suitable for the applications described above, there has also been a demand for, for example, a phosphor that emits red to near-infrared light and has a higher light emission intensity.

One object of the present disclosure is to provide an oxide phosphor configured to emit light having a light emission peak wavelength in a wavelength range from red light to near-infrared light upon irradiation with excitation light, and a light emitting device.

### SUMMARY

According to a first aspect of the present disclosure, an oxide phosphor has a composition represented by the following formula (1).

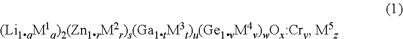

wherein M¹ represents at least one element selected from the group consisting of Na, K, Rb, and Cs; M² represents at least one element selected from the group consisting of Mg, Ca, Sr, and Ba; M³ represents at least one element selected from the group consisting of Al, Sc, and In; M⁴ represents at least one element selected from the group consisting of Si, Ti, Zr, Sn, and Hf; M⁵ represents at least one element selected from the group consisting of Ni, Ce, Eu, Fe, Mn, Nd, Tm, Ho, Er, and Yb; q, r, s, t, u, v, w, and x satisfy 0≤q≤0.5, 0≤r≤1.0, 0≤s≤4.0, 0≤t≤1.0, 5≤u≤10, 0≤v≤1.0, 0.5≤w≤5.0, and 10≤x≤30; and y and z satisfy 0.02≤y≤0.5, 0≤z≤0.3, and y>z.

According to a second aspect of the present disclosure, a light emitting device includes the oxide phosphor, and a light emitting element configured to emit light having a light emission peak wavelength in a range of 365 nm or more and 650 nm or less and to irradiate the oxide phosphor with the light.

The aspects of the present disclosure allow for providing an oxide phosphor configured to emit light having a light emission peak wavelength in a wavelength range from red light to near-infrared light, which is in a range of 680 nm or more and 1,500 nm or less, upon irradiation with excitation light, and a light emitting device.

### BRIEF DESCRIPTION OF THE DRAWINGS

FIG. 1 is a schematic cross-sectional view showing an exemplary light emitting device according to a first embodiment of the present disclosure.

FIG. 2 is a schematic cross-sectional view showing another exemplary light emitting device according to the first embodiment of the present disclosure.

FIG. 3 is a schematic plan view showing an exemplary light emitting device according to a second embodiment of the present disclosure.

FIG. 4 is a schematic cross-sectional view showing an exemplary light emitting device according to the second embodiment of the present disclosure.

FIG. 5 is a graph showing light emission spectra of oxide phosphors according to Examples 1 and 2 and Comparative Example 1.

FIG. 6 is a graph showing light emission spectra of oxide phosphors according to Examples 3 and 4.

FIG. 7 is a graph showing light emission spectra of oxide phosphors according to Examples 5 and 6.

FIG. 8 is a graph showing light emission spectra of oxide phosphors according to Examples 7 and 8.

FIG. 9 is a graph showing light emission spectra of oxide phosphors according to Examples 9 and 10.

FIG. 10 is a graph showing light emission spectra of oxide phosphors according to Examples 11 and 12.

FIG. 11 is a graph showing light emission spectra of oxide phosphors according to Examples 13, 14, and 15.

FIG. 12 is a graph showing light emission spectra of oxide phosphors according to Examples 16, 17, and 18.

FIG. 13 is a graph showing light emission spectra of oxide phosphors according to Examples 19 and 20.

### DETAILED DESCRIPTION

The oxide phosphor and the light emitting device according to the present disclosure will be described below. The embodiments described below are intended to give a concrete form to the technical idea of the present disclosure, and the present disclosure is not limited to the following oxide phosphor, light emitting device, and method for producing an oxide phosphor. For visible light, the relationship between color names and chromaticity coordinates, and the relationship between wavelength ranges of light and color names of monochromatic light are in accordance with Japanese Industrial Standard (JIS) Z8110.

Light emitting devices using a phosphor are needed to emit light in an appropriate wavelength range according to a visual object or conditions of use. For example, in the medical field, there may be a need to easily obtain information inside a living body. The living body includes light absorbers such as water, hemoglobin, and melanin. For example, hemoglobin has a high light absorptance in a visible light wavelength range of less than 650 nm. With a light emitting device that emits light in the visible light wavelength range, the light in the visible light wavelength range is less easily transmitted through the living body, which makes it difficult to obtain information inside the living body. If it is possible to irradiate light in a wavelength range where absorption and scattering of light in living tissues are reduced, it becomes easier to obtain information deep inside the living body. Therefore, there is a need for a light emitting device that can emit light in a wavelength range referred to as a “biological window” where light easily transmits through the living body. The “biological window” may be referred to as a “first biological window” in a wavelength range of approximately 650 nm to approximately 950 nm, may be referred to as a “second biological window” in a wavelength range of approximately 1,000 nm to approximately 1,350 nm, and may be referred to as a “third biological window” in a wavelength range of approximately 1,500 nm to approximately 1,800 nm. For example, if the increase or decrease of oxygen concentration in the blood in the living body can be measured by measuring the increase or decrease of light absorption due to hemoglobin that binds to oxygen, the information inside the living body can be easily obtained by irradiation with the light emitted from the light emitting device. If the information deep inside the living body can be obtained by irradiation with the light emitted from the phosphor and the light emitting element instead of irradiating X-rays or others, it is possible to obtain the information inside the living body more safely. Therefore, the phosphor used in the light emitting device may be needed to emit light having a light emission peak wavelength in a wavelength range from red light to near-infrared light. The phosphor used in the light emitting device may be needed to emit light having a light emission peak wavelength in a range of 680 nm or more and 1,500 nm or less, preferably 700 nm or more and 1,500 nm or less, or a light emission peak wavelength in a range of 700 nm or more and 1,400 nm or less, upon irradiation with excitation light emitted from a light emitting element having a light emission peak wavelength in a range of 365 nm or more and 650 nm or less. Recently, there is a need for a light emitting device that emits light in a wavelength range from red light to near-infrared light, which allows for more clearly visualizing deep inside the living body and is highly safe. When a light emitting device including a light emitting element and a phosphor includes a phosphor having a high light emission intensity that can emit light with a high output power, detection capability can be improved, making it easier to obtain information inside the living body.

In the agricultural and food fields, there is a need for non-destructive sugar content meters for non-destructively measuring the sugar content of agricultural products and fruits and vegetables, as well as measuring instruments (such as the Taste Analyzer (registered trademark)) that can non-destructively measure the taste of food such as rice. Near-infrared spectroscopy may be used as a non-destructive method for measuring internal quality such as sugar content, acidity, ripeness, and internal damage of fruits and vegetables, and the outer-layer quality such as abnormal drying appearing on the skin surface of fruits and vegetables or in the outer layer near the skin surface. In the near-infrared spectroscopy, fruits and vegetables are irradiated with light in the near-infrared light wavelength range, the transmitted light that is transmitted through the fruits and vegetables and the reflected light that is reflected by the fruits and vegetables are received, and the quality of the fruits and vegetables is measured by measuring the decrease in light intensity (light absorption). Light sources such as tungsten or xenon lamps are used in near-infrared spectroscopy analysis devices used in such food fields. The general rules for near-infrared spectrophotometric analysis in JIS K0134 state that near-infrared rays refers to a ray having a wavelength of 700 nm or more and 2,500 nm or less.

In the face of environmental changes such as climate change, it is also desirable to stably supply plants such as vegetables and to increase the production efficiency of plants. Plant factories that can be artificially controlled can stably supply safe vegetables to the market and are expected to be a next-generation industry. Such plant factories need a light emitting device that emits light capable of promoting the growth of plants. Reactions of plants to light can be grouped into photosynthesis and photomorphogenesis. Photosynthesis is a reaction that uses light energy to decompose water, generate oxygen, and fix carbon dioxide to organic materials, which is a necessary reaction for the growth of plants. Photomorphogenesis is a morphogenetic reaction that uses light as a signal for seed germination, differentiation (germ formation, leaf formation), movement (pore opening and closing, chloroplast movement), and photorefraction. In the photomorphogenesis, it has been found that light with the wavelength of 690 nm or more and 800 nm or less affects the photoreceptors of plants. Therefore, light emitting devices used in plant factories may be needed to be capable of emitting light in the wavelength range that affects plant photoreceptors (chlorophyll a, chlorophyll b, carotenoids, phytochromes, cryptochromes, and phototropins) and promotes the growth of plants.

For use in the light emitting device using a light emitting element such as a light emitting diode (LED) or laser diode (LD) configured to emit light in a range of purple to blue as an excitation light source, the above-mentioned near-infrared light emitting phosphor is also needed to have a high light emission intensity so as to enable light emission suitable for the application and to enable more accurate detection.

Further, in some cases, light emitting devices that emit light in a wavelength range of 365 nm or more and less than 700 nm as well as light in the wavelength range from red light to near-infrared light is needed. For example, there is a case in which it is necessary to emit light in the visible light wavelength range not only to obtain internal information on living bodies, fruits, and vegetables, but also to enhance the visibility of objects.

The oxide phosphor has a composition represented by the following formula (1).

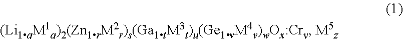

wherein M¹ represents at least one element selected from the group consisting of Na, K, Rb, and Cs; M² represents at least one element selected from the group consisting of Mg, Ca, Sr, and Ba; M³ represents at least one element selected from the group consisting of Al, Sc, and In; M⁴ represents at least one element selected from the group consisting of Si, Ti, Zr, Sn, and Hf; M⁵ represents at least one element selected from the group consisting of Ni, Ce, Eu, Fe, Mn, Nd, Tm, Ho, Er, and Yb; q, r, s, t, u, v, w, and x satisfy 0≤q≤0.5, 0≤r≤1.0, 0≤s≤4.0, 0≤t≤1.0, 5≤u≤10, 0≤v≤1.0, 0.5≤w≤5.0, and 10≤x≤30; and y and z satisfy 0.02≤y≤0.5, 0≤z≤0.3, and y>z.

In the present specification, the term “molar ratio” represents the ratio of each element in 1 mol of the chemical composition of the phosphor, unless otherwise specified. In the present specification, plural elements sectioned by comma (,) in the compositional formula mean that at least one of these plural elements is contained in the composition. In the present specification, in the composition formula representing the composition of the phosphor, the part before the colon (:) represents elements constituting a host crystal and its molar ratio, and the part after the colon (:) represents an activating element. In the present specification, the terms “M¹”, “M²”, “M³”, “M⁴”, and “M⁵” in the composition represented by the formula (1) may be represented as “element M¹”, “element M²”, “element M³”, “element M⁴”, and “element M⁵”, respectively.

The oxide phosphor having a composition represented by the formula (1) contains Cr serving as an activating element in the formula (1). In the formula (1) of the oxide phosphor, the parameter y, which represents a molar ratio of Cr serving as an activating element, satisfies 0.02 or more and 0.5 or less (0.02≤y≤0.5), preferably 0.02 or more and 0.4 or less (0.02≤y≤0.4), more preferably more than 0.02 and 0.3 or less (0.02<y≤0.3), even more preferably more than 0.02 and 0.2 or less (0.02<y≤0.2), and particularly preferably 0.025 or more and 0.18 or less (0.025≤y≤0.18). In the formula (1) of the oxide phosphor, the parameter y, which represents a molar ratio of Cr serving as an activating element, satisfies 0.02 or more and 0.5 or less (0.02≤y≤0.5), and thus the oxide phosphor can emit light having a higher light emission intensity in a wavelength range from red light to near-infrared light upon irradiation with excitation light.

The oxide phosphor having a composition represented by the formula (1), upon irradiation with excitation light, preferably emits light having a light emission peak wavelength in a range of 680 nm or more and 1,500 nm or less, more preferably 680 nm or more and 1,400 nm or less, even more preferably 680 nm or more and 1,200 nm or less, still more preferably 680 nm or more and 1,000 nm or less, and particularly preferably 680 nm or more and 900 nm or less, in the light emission spectrum of the oxide phosphor. The excitation light may be light having a light emission peak wavelength in a range of 365 nm or more and 650 nm or less. When the oxide phosphor emits light having a light emission peak wavelength in a range of 680 nm or more and 1,500 nm or less in the light emission spectrum upon irradiation with excitation light, the oxide phosphor can be used in a light emitting device for obtaining information inside a living body, a light emitting device for non-destructively obtaining information on agricultural products and fruits and vegetables, and a light emitting device for promoting growth of plants such as vegetables.

The oxide phosphor having a composition represented by the formula (1) preferably has a full width at half maximum in a range of 5 nm or more and 250 nm or less, more preferably 7 nm or more and 250 nm or less, even more preferably 15 nm or more and 250 nm or less, still more preferably 40 nm or more and 250 nm or less, and particularly preferably 40 nm or more and 245 nm or less, in the light emission spectrum.

In the present specification, the full width at half maximum refers to a wavelength width where the light emission intensity is 50% of the maximum light emission intensity in the light emission spectrum at the light emission peak wavelength. Light is absorbed and scattered in a living body, and to measure a subtle change in the propagation behavior of light in the blood in a living body, it is preferable to irradiate light having a wide full width at half maximum in the light emission spectrum. Even in the case of non-destructive measurement of information on agricultural products and fruits and vegetables, it is also preferable to irradiate light having a wide full width at half maximum in the light emission spectrum to obtain information on the inside of the agricultural products and fruits and vegetables. For the color appearance of an object when irradiated with light (hereinafter, also referred to as “color rendering property”), it is desirable to exhibit a light emission spectrum in a wider wavelength range, and the wider the full width at half maximum, the better the color rendering property of light can be emitted. For example, when used in a work environment such as a factory, it may be necessary to emit light that does not disturb the spectral balance of the light in the work environment so that workers can work comfortably.

The oxide phosphor preferably has a light emission peak wavelength in a range of 700 nm or more and 900 nm or less, more preferably 710 nm or more and 890 nm or less, in the composition represented by the formula (1). When the oxide phosphor having a composition represented by the formula (1) emits light having a light emission peak wavelength in a range of 700 nm or more and 900 nm or less in the light emission spectrum of the oxide phosphor upon irradiation with excitation light, the oxide phosphor can be used in a light emitting device for obtaining information inside a living body, a light emitting device for non-destructively obtaining information on agricultural products and fruits and vegetables, and a light emitting device for promoting growth of plants such as vegetables.

The oxide phosphor having a composition represented by the formula (1) has a configuration in which part or all of Ga in the composition is replaced with one or more elements selected from the group consisting of Zn, an element M², an element M³, Ge, and an element M⁴ in an oxide phosphor having a composition represented by the following formula (a), and thus can emit light having a higher light emission intensity in the wavelength range from red light to near-infrared light than that of the oxide phosphor having a composition in which Ga in the composition represented by the following formula (a) is not replaced with other elements, upon irradiation with excitation light. It is not clear why the oxide phosphor having a composition represented by the formula (1) (part of Ga in the composition represented by the following formula (a) is replaced with one or more elements selected from the group consisting of Zn, an element M², an element M³, Ge, and an element M⁴) has a higher light emission intensity than that of the oxide phosphor having a composition represented by the following formula (a). It is presumed that by replacing part or all of Ga in the composition represented by the following formula (a) with Zn and/or Ge, which are highly reactive and thus easily react at relatively low temperatures (e.g., 1,200° C. or higher and 1,600° C. or lower, preferably 1,200° C. or higher and 1,500° C. or lower), the oxide phosphor having a composition represented by the formula (1) has improved crystallinity and can emit light having a higher light emission intensity upon irradiation with excitation light. It is also presumed that by replacing part or all of Ga in the composition represented by the following formula (a) with one or more elements selected from the group consisting of Zn, an element M², an element M³, Ge, and an element M⁴, the oxide phosphor having a composition represented by the formula (1) has a change in crystal symmetry, and the change in crystal symmetry allows Cr serving as an activating element to be properly distributed in the crystal structure and concentration quenching to be less likely to occur, thereby enabling emission of light having a higher light emission intensity upon irradiation with excitation light. The element M² is at least one element selected from the group consisting of Mg, Ca, Sr, and Ba. The element M⁴ is at least one element selected from the group consisting of Si, Ti, Zr, Sn, and Hf.

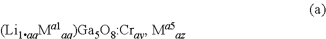

In the formula (a), M^{a1} represents at least one element selected from the group consisting of Na, K, Rb, and Cs; M^{a5} represents at least one element selected from the group consisting of Ni, Ce, Eu, Fe, Mn, Nd, Tm, Ho, Er, and Yb; aq satisfies 0≤aq≤0.5; and when a molar ratio of Li or a total molar ratio of Li and M^{a1} is 1, ay and az satisfy 0.02≤ay≤0.5, 0≤az≤0.3, and ay>az relative to the molar ratio of Li or the total molar ratio of Li and M^{a1}.

The oxide phosphor having a composition represented by the formula (1) has a composition in which part of Ga in the composition is replaced with one or more elements selected from the group consisting of Zn, the element M², the element M³, Ge, and the element M⁴, and thus has a composition different from that of the oxide phosphor having a composition represented by the formula (a).

In the composition of the oxide phosphor represented by the formula (1), the parameter s, which represents a molar ratio of Zn, the element M², or the sum of Zn and the element M², is 0 or more and 4.0 or less (0≤s≤4.0), may be 1.0 or more and 3.5 or less (1.0≤s≤3.5), may be 1.0 or more and 2.0 or less (1.0≤s≤2.0), or may be 1.0 (s=1.0).

In the composition represented by the formula (1), the oxide phosphor does not have to contain Mg as the element M². In the composition represented by the formula (1), the element M² may be at least one selected from the group consisting of Ca, Sr, and Ba. In the composition represented by the formula (1), when the oxide phosphor does not contain Mg as the element M², the parameter r, which represents a molar ratio of the element M², is preferably 0.5 or less. In the composition of the oxide phosphor represented by the formula (1), the element M² may be at least one selected from the group consisting of Ca, Sr, and Ba, and the parameter r may satisfy 0≤r≤0.5.

In the composition represented by the formula (1), the oxide phosphor does not have to contain the element M², and the parameter r, which represents a molar ratio of the element M², may be 0 (r=0). In the composition represented by the formula (1), when the oxide phosphor does not contain the element M² and the parameter r, which represents a molar ratio of the element M², is 0, the parameter w, which represents a molar ratio of Ge or the sum of Ge and the element M⁴, is 0.5 or more and 5.0 or less (0.5≤w≤5.0), may be 0.6 or more and 4.0 or less (0.6≤w≤4.0), or may be 0.8 or more and 3.0 or less (0.8≤w≤3.0).

In the composition represented by the formula (1), when the oxide phosphor contains Zn, and does not contain Mg as the element M² or does not contain the element M², the parameter w, which represents a molar ratio of Ge, the element M⁴, or the sum of Ge and the element M⁴, may be 1.3 or more and 3.2 or less (1.3≤w≤3.2), or may be 1.5 or more and 3.0 or less (1.5≤w≤3.0).

The oxide phosphor may have a composition represented by the following formula (1a), which is included in the composition represented by the formula (1).

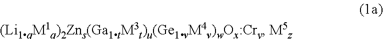

In the formula (1a), M¹ represents at least one element selected from the group consisting of Na, K, Rb, and Cs; M³ represents at least one element selected from the group consisting of Al, Sc, and In; M⁴ represents at least one element selected from the group consisting of Si, Ti, Zr, Sn, and Hf; M⁵ represents at least one element selected from the group consisting of Ni, Ce, Eu, Fe, Mn, Nd, Tm, Ho, Er, and Yb; q, s, t, u, v, w, and x satisfy 0≤q≤0.5, 1.0≤s≤4.0, preferably 1.0≤s≤3.5, 0≤t≤1.0, 5≤u≤10, 0≤v≤1.0, 0.5≤w≤5.0, may preferably satisfy 0.8≤w≤3.2, and satisfy, 10≤x≤30; and y and z satisfy 0.02<y≤0.5, 0≤z≤0.3, and y>z.

In the composition represented by the formula (1), when the oxide phosphor contains Zn, and does not contain Mg as the element M² or does not contain the element M², the oxide phosphor preferably has a full width at half maximum in a range of 40 nm or more and 250 nm or less, more preferably 50 nm or more and 245 nm or less, even more preferably 60 nm or more and 245 nm or less, and particularly preferably 70 nm or more and 245 nm or less, in the light emission spectrum. When the oxide phosphor has a full width at half maximum in a range of 40 nm or more and 250 nm or less in the light emission spectrum, the oxide phosphor can be used in a light emitting device for obtaining information inside a living body, a light emitting device for non-destructively obtaining information on agricultural products and fruits and vegetables, and a light emitting device for promoting growth of plants such as vegetables.

In the composition represented by the formula (1), when the oxide phosphor contains Zn, does not contain Mg as the element M² or does not contain the element M², and the parameter w, which represents a molar ratio of Ge, the element M⁴, or the sum of Ge and the element M⁴, is 1.3 or more and 3.2 or less (1.3≤w≤3.2), the oxide phosphor preferably has a full width at half maximum in a range of 190 nm or more and 250 nm or less, more preferably 200 nm or more and 245 nm or less, and even more preferably 205 nm or more and 245 nm or less, in the light emission spectrum. When the oxide phosphor has a wider full width at half maximum in a range of 190 nm or more and 250 nm or less in the light emission spectrum, the oxide phosphor can easily obtain information in a living body and non-destructively obtain information on agricultural products and fruits and vegetables, and thus can be used in a light emitting device capable of obtaining such information and a light emitting device configured to emit light for promoting growth of plants such as vegetables.

In the composition represented by the formula (1), when the oxide phosphor contains Zn, and does not contain Mg as the element M² or does not contain the element M², the oxide phosphor preferably has a light emission peak wavelength in a range of 700 nm or more and 900 nm or less, more preferably 710 nm or more and 890 nm or less, in the light emission spectrum. When the oxide phosphor emits light having a light emission peak wavelength in a range of 700 nm or more and 900 nm or less in the light emission spectrum of the oxide phosphor upon irradiation with excitation light, the oxide phosphor can be used in a light emitting device for obtaining information inside a living body, a light emitting device for non-destructively obtaining information on agricultural products and fruits and vegetables, and a light emitting device for promoting growth of plants such as vegetables.

In the composition represented by the formula (1), when the oxide phosphor contains Zn, does not contain Mg as the element M² or does not contain the element M², and the parameter w, which represents a molar ratio of Ge, the element M⁴, or the sum of Ge and the element M⁴, is 1.3 or more and 3.2 or less (1.3≤w≤3.2), the oxide phosphor preferably has a light emission peak wavelength in a range of 750 nm or more and 900 nm or less, more preferably 770 nm or more and 890 nm or less, and even more preferably 780 nm or more and 885 nm or less, in the light emission spectrum. When the oxide phosphor emits light having a light emission peak wavelength in a range of 750 nm or more and 900 nm or less and having a light emission peak wavelength in the wavelength range of near-infrared light in the light emission spectrum upon irradiation with excitation light, the oxide phosphor can easily obtain information in a living body and non-destructively obtain information on agricultural products and fruits and vegetables, and thus can be used in a light emitting device capable of obtaining such information and a light emitting device configured to emit light for promoting growth of plants such as vegetables.

In the composition of the oxide phosphor represented by the formula (1), s and v may satisfy s=0 and v=0. In the composition represented by the formula (1), when s is 0 (s=0), the oxide phosphor does not contain Zn and the element M² in the composition represented by the formula (1). In the composition represented by the formula (1), when v satisfies v=0, the oxide phosphor does not contain the element M⁴ in the composition represented by the formula (1).

The oxide phosphor may have a composition represented by the following formula (1b), which is included in the composition represented by the formula (1).

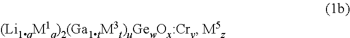

In the formula (1b), M¹ represents at least one element selected from the group consisting of Na, K, Rb, and Cs; M³ represents at least one element selected from the group consisting of Al, Sc, and In; M⁵ represents at least one element selected from the group consisting of Ni, Ce, Eu, Fe, Mn, Nd, Tm, Ho, Er, and Yb; q, t, u, w, and x satisfy 0≤q≤0.5, 0≤t≤1.0, 5≤u≤10, 0.5≤w≤5.0, preferably 0.8≤w≤3.2, may satisfy 1.0≤w≤3.0, and satisfy 10≤x≤30, preferably 12≤x≤20; and y and z satisfy 0.02≤y≤0.5, 0≤z≤0.3, and y>z.

In the composition represented by the formula (1), when s and v satisfy s=0 and v=0, and the oxide phosphor does not contain Zn, the element M², and the element M⁴, the oxide phosphor preferably has a full width at half maximum in a range of 190 nm or more and 240 nm or less, more preferably 200 nm or more and 235 nm or less, and even more preferably 210 nm or more and 230 nm or less, in the light emission spectrum. When the oxide phosphor has a wider full width at half maximum in a range of 190 nm or more and 240 nm or less in the light emission spectrum, the oxide phosphor can easily obtain information in a living body and non-destructively obtain information on agricultural products and fruits and vegetables, and thus can be used in a light emitting device capable of obtaining the information and a light emitting device configured to emit light for promoting growth of plants such as vegetables.

In the composition represented by the formula (1), when s and v satisfy s=0 and v=0, and the oxide phosphor does not contain Zn, the element M², and the element M⁴, the oxide phosphor preferably has a light emission peak wavelength in a range of 800 nm or more and 860 nm or less, more preferably 810 nm or more and 850 nm or less, and even more preferably 820 nm or more and 840 nm or less, in the light emission spectrum. When the oxide phosphor emits light having a light emission peak wavelength in a range of 800 nm or more and 860 nm or less and having a light emission peak wavelength in the wavelength range of near-infrared light in the light emission spectrum upon irradiation with excitation light, the oxide phosphor can easily obtain information in a living body and non-destructively obtain information on agricultural products and fruits and vegetables, and thus can be used in a light emitting device capable of obtaining the information and a light emitting device configured to emit light for promoting growth of plants such as vegetables.

In the composition of the oxide phosphor represented by the formula (1), s and v may satisfy s=0 and v=1.0. In the composition represented by the formula (1), when s is 0 (s=0), the oxide phosphor does not contain Zn and the element M² in the composition represented by the formula (1). In the composition represented by the formula (1), when v satisfies v=1.0, the oxide phosphor does not contain Ge in the composition represented by the formula (1). In the composition of the oxide phosphor represented by the formula (1), the element M⁴ is Si, and s and v may satisfy s=0 and v=1.0.

The oxide phosphor may have a composition represented by the following formula (1c), which is included in the composition represented by the formula (1).

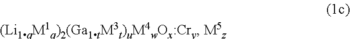

In the formula (1c), M¹ represents at least one element selected from the group consisting of Na, K, Rb, and Cs; M³ represents at least one element selected from the group consisting of Al, Sc, and In; M⁴ represents at least one element selected from the group consisting of Si, Ti, Zr, Sn, and Hf; M⁴ may be Si; M⁵ represents at least one element selected from the group consisting of Ni, Ce, Eu, Fe, Mn, Nd, Tm, Ho, Er, and Yb; q, t, u, w, and x satisfy 0≤q≤0.5, 0≤t≤1.0, 5≤u≤10, 0.5≤w≤5.0, preferably 0.8≤w≤3.2, may satisfy 1.0≤w≤3.0, and satisfy 10≤x≤30, preferably 12≤x≤20; and y and z satisfy 0.02≤y≤0.5, 0≤z≤0.3, and y>z.

The oxide phosphor may have a composition represented by the following formula (1c-1), which is included in the composition represented by the formula (1).

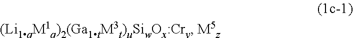

In the formula (1c-1), M¹ represents at least one element selected from the group consisting of Na, K, Rb, and Cs; M³ represents at least one element selected from the group consisting of Al, Sc, and In; M⁵ represents at least one element selected from the group consisting of Ni, Ce, Eu, Fe, Mn, Nd, Tm, Ho, Er, and Yb; q, t, u, w, and x satisfy 0≤q≤0.5, 0≤t≤1.0, 5≤u≤10, 0.5≤w≤5.0, preferably 0.8≤w≤3.2, may satisfy 1.0≤w≤3.0, and satisfy 10≤x≤30, preferably 12≤x≤20; and y and z satisfy 0.02≤y≤0.5, 0≤z≤0.3, and y>z.

In the composition represented by the formula (1), when the element M⁴ is Si, s and v satisfy s=0 and v=1.0, and the oxide phosphor does not contain Zn and the element M², the oxide phosphor preferably has a full width at half maximum in a range of 30 nm or less, more preferably 20 nm or less, and may have a full width at half maximum of 5 nm or more, in the light emission spectrum. When the oxide phosphor has a full width at half maximum of 30 nm or less in the light emission spectrum, the oxide phosphor has a relatively narrow full width at half maximum, and even when used in a work environment such as a factory, the oxide phosphor can emit light that does not disturb the spectral balance of the light in the work environment so that workers can work comfortably.

In the composition represented by the formula (1), when the element M⁴ is Si, s and v satisfy s=0 and v=1.0, and the oxide phosphor does not contain Zn and the element M², the oxide phosphor preferably has a light emission peak wavelength in a range of 690 nm or more and 720 nm or less, more preferably 700 nm or more and 720 nm or less, in the light emission spectrum. When the oxide phosphor emits light having a light emission peak wavelength in a range of 690 nm or more and 720 nm or less and having a light emission peak wavelength in the wavelength range from red light to near-infrared light in the light emission spectrum upon irradiation with excitation light, and when used in a light emitting device for obtaining information inside a living body or for non-destructively obtaining information on agricultural products and fruits and vegetables, or a light emitting device for promoting growth of plants such as vegetables, the oxide phosphor can emit light that does not disturb the spectral balance of the light in the work environment so that workers can work comfortably.

In the composition represented by the formula (1), the oxide phosphor contains Mg as the element M² and may contain at least one element selected from the group consisting of Ca, Sr, and Ba in addition to Mg as the element M². In the composition of the oxide phosphor represented by the formula (1), the element M² is Mg, and r may be 1 (r=1.0). In the composition represented by the formula (1), when r is 1 (r=1.0), the oxide phosphor does not contain Zn. In the composition represented by the formula (1), when r is 1 (r=1.0), the oxide phosphor preferably contains Mg as the element M² and may contain at least one element selected from the group consisting of Ca, Sr, and Ba in addition to Mg as the element M².

In the composition represented by the formula (1), when the oxide phosphor contains Mg as the element M² and r is 1.0 (r=1.0), the oxide phosphor preferably has a full width at half maximum in a range of 50 nm or more and 130 nm or less, more preferably 50 nm or more and 125 nm or less, in the light emission spectrum. When the oxide phosphor has a full width at half maximum in a range of 50 nm or more and 130 nm or less in the light emission spectrum, the oxide phosphor has a relatively narrow full width at half maximum, and even when used in a work environment such as a factory, the oxide phosphor can emit light that does not disturb the spectral balance of the light in the work environment so that workers can work comfortably.

In the composition represented by the formula (1), when the oxide phosphor contains Mg as the element M² and r is 1.0 (r=1.0), the oxide phosphor preferably has a light emission peak wavelength in a range of 680 nm or more and 730 nm or less, more preferably 690 nm or more and 730 nm or less, in the light emission spectrum. When the oxide phosphor emits light having a light emission peak wavelength in a range of 680 nm or more and 730 nm or less in the light emission spectrum of the oxide phosphor upon irradiation with excitation light, and when used in a light emitting device for obtaining information inside a living body or for non-destructively obtaining information on agricultural products and fruits and vegetables, or a light emitting device for promoting growth of plants such as vegetables, the oxide phosphor can emit light that does not disturb the spectral balance of the light in the work environment so that workers can work comfortably.

The light emitting device includes the oxide phosphor having a composition represented by the formula (1), and a light emitting element being configured to irradiate the oxide phosphor with excitation light and having a light emission peak wavelength in a range of 365 nm or more and 650 nm or less. The oxide phosphor is preferably contained in a wavelength conversion member, and the wavelength conversion member may contain a light-transmissive material.

A semiconductor element can be used as the light emitting element configured to irradiate the oxide phosphor with excitation light. For example, a nitride semiconductor can be selected as the material for the light emitting element that emits green or blue light. Materials such as In_{X}Al_{Y}Ga_{1-X-Y}N (0≤X≤1, 0≤Y≤1, X+Y≤1) can be used as the material for the semiconductor structure constituting the light emitting element. For example, a gallium-aluminum-arsenic semiconductor or an aluminum-indium-gallium-phosphorus semiconductor can be selected as the material for the light emitting element that emits red-based color light. For example, an LED chip or an LD chip is preferably used for the light emitting element.

The light emitting element has a light emission peak wavelength in a range of 365 nm or more and 650 nm or less, may have a light emission peak wavelength in a range of 365 nm or more and 500 nm or less, may have a light emission peak wavelength in a range of 370 nm or more and 490 nm or less, or may have a light emission peak wavelength in a range of 375 nm or more and 480 nm or less. The light emitting element may have a light emission peak wavelength in a range of more than 500 nm and 650 nm or less, may have a light emission peak wavelength in a range of 510 nm or more and 650 nm or less, or may have a light emission peak wavelength in a range of 520 nm or more and 650 nm or less. Using the light emitting element as the excitation light source of the oxide phosphor can constitute a light emitting device that emits mixed color light in which light emitted from the light emitting element and fluorescence emitted from the phosphor containing the oxide phosphor in a desired wavelength range. The full width at half maximum of the light emission peak in the light emission spectrum of the light emitting element can be, for example, 30 nm or less. For example, a light emitting element using a nitride-based semiconductor is preferably used for the light emitting element. Using the light emitting element employing a nitride semiconductor as the excitation light source can achieve a stable light emitting device having high efficiency, high input-output linearity, and high resistance to mechanical impacts.

The light emitting device may essentially include a first phosphor containing the oxide phosphor described above and further include a phosphor having a composition different from that. The light emitting device preferably includes, in addition to the first phosphor, at least one phosphor selected from the group consisting of a second phosphor having a light emission peak wavelength in a range of 455 nm or more and less than 495 nm, a third phosphor having a light emission peak wavelength in a range of 495 nm or more and less than 610 nm, a fourth phosphor having a light emission peak wavelength in a range of 610 nm or more and less than 700 nm, and a fifth phosphor having a light emission peak wavelength in a range of 700 nm or more and 1,600 nm or less, in the light emission spectrums of respective phosphors. When the light emitting device includes a light emitting element, a first phosphor containing the oxide phosphor described above, and at least one phosphor selected from the group consisting of a second phosphor, a third phosphor, a fourth phosphor, and a fifth phosphor, the light emitting device can be used as a light source that emits light having a light emission spectrum in a wavelength range from visible light to a part of near-infrared light. The light emitting device can be used as a light source that has a light emission spectrum like that of conventionally used tungsten and xenon lamps and can be reduced in size compared to tungsten and xenon lamps. A small light emitting device can be mounted on small mobile devices such as smartphones and smartwatches to obtain information in a living body, which can be used to manage physical conditions.

The light emitting device can be used, for example, in a reflection spectroscopic measuring device, and a lighting device that allows non-destructive measurement in a living body, fruits, vegetables, and the like and that needs light with a good color rendering property.

The second phosphor, which has a composition different from that of the first phosphor containing the oxide phosphor described above, preferably contains at least one phosphor selected from the group consisting of a phosphate phosphor having a composition represented by the following formula (2a), an aluminate phosphor having a composition represented by the following formula (2b), and an aluminate phosphor having a composition represented by the following formula (2c); and may contain two or more phosphors of these.

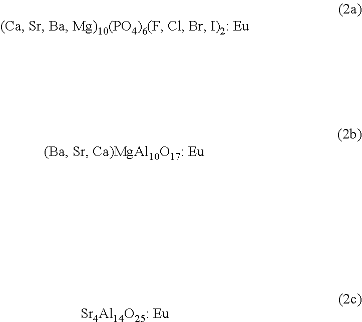

The third phosphor preferably contains at least one phosphor selected from the group consisting of a silicate phosphor having a composition represented by the following formula (3a), an aluminate phosphor or a gallate phosphor having a composition represented by the following formula (3b), a β-SiAlON phosphor having a composition represented by the following formula (3c), a cesium lead halide phosphor having a composition represented by the following formula (3d), and a nitride phosphor having a composition represented by the following formula (3e); and may contain two or more phosphors of these. In the case where the third phosphor contains two or more phosphors, each of the two or more third phosphors preferably has a light emission peak wavelength in a range different from each other within a range of 495 nm or more and less than 610 nm.

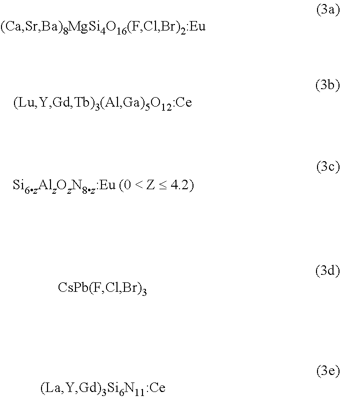

The fourth phosphor preferably contains at least one phosphor selected from the group consisting of a nitride phosphor having a composition represented by the following formula (4a), a fluoro-germanate phosphor having a composition represented by the following formula (4b), an oxynitride phosphor having a composition represented by the following formula (4c), a fluoride phosphor having a composition represented by the following formula (4d), a fluoride phosphor having a composition represented by the following formula (4e), a nitride phosphor having a composition represented by the following formula (40, and a nitride phosphor having a composition represented by the following formula (4g); and may contain two or more phosphors of these. In the case where the fourth phosphor contains two or more phosphors, each of the two or more fourth phosphors preferably has a light emission peak wavelength in a range different from each other within a range of 610 nm or more and less than 700 nm.

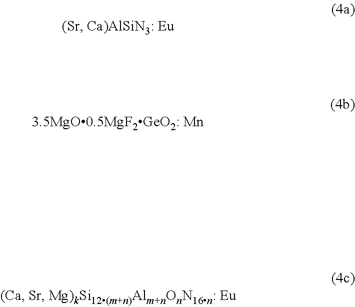

wherein k, m, and n satisfy 0<k≤2.0, 2.0≤m≤6.0, and 0≤n≤2.0.

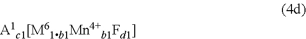

wherein A¹ includes at least one selected from the group consisting of K⁺, Li⁺, Na⁺, Rb⁺, Cs⁺, and NH₄⁺, among which K⁺ is preferred; M⁶ includes at least one element selected from the group consisting of Group 4 elements and Group 14 elements, among which Si and Ge are preferred; b1 satisfies 0<b1<0.2; c1 represents an absolute value of a charge of [M⁶_{1-b1}Mn⁴⁺_{b1}F_{d1}] ions; and d1 satisfies 5<d1<7.

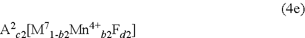

wherein A² includes at least one selected from the group consisting of K⁺, Li⁺, Na⁺, Rb⁺, Cs⁺, and NH₄⁺, among which K⁺is preferred; M⁷ includes a Group 13 element, and may further include at least one element selected from the group consisting of Group 4 elements and Group 14 elements, among which Al is preferred in the Group 13 elements and Si is preferred in the Group 14 elements; b2 satisfies 0<b2<0.2; c2 represents an absolute value of a charge of [M⁷_{1-b2}Mn⁴⁺_{b2}F_{d2}] ions; and d2 satisfies 5<d2<7.

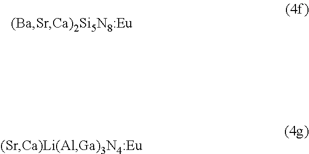

The fifth phosphor preferably contains at least one phosphor selected from the group consisting of a gallate phosphor having a composition represented by the following formula (5a), an aluminate phosphor having a composition represented by the following formula (5b), a phosphor having a composition represented by the following formula (5c) different from those of the above oxide phosphors, a phosphor having a composition represented by the following formula (5d) different from those of the above oxide phosphors, a phosphor having a composition represented by the following formula (5e) different from those of the above oxide phosphors, a phosphor having a composition represented by the following formula (5f) different from those of the above oxide phosphors, a phosphor having a composition represented by the following formula (5g) different from those of the above oxide phosphors, a phosphor having a composition represented by the following formula (5h) different from those of the above oxide phosphors, a phosphor having a composition represented by the following formula (5i) different from those of the above oxide phosphors, a phosphor having a composition represented by the following formula (5j) different from those of the above oxide phosphors, a phosphor having a composition represented by the following formula (5k) different from those of the above oxide phosphors, a phosphor having a composition represented by the following formula (5l) different from those of the above oxide phosphors, a phosphor having a composition represented by the following formula (5m) different from those of the above oxide phosphors, a phosphor having a composition represented by the following formula (5n) different from those of the above oxide phosphors, and a phosphor having a composition represented by the following formula (5o) different from those of the above oxide phosphors; and may contain two or more phosphors of these.

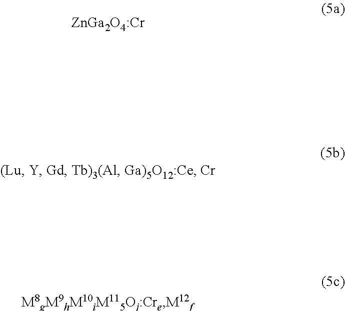

wherein M⁸ represents at least one element selected from the group consisting of Li, Na, K, Rb, and Cs; M⁹ represents at least one element selected from the group consisting of Mg, Ca, Sr, Ba, and Zn; M¹⁰ represents at least one element selected from the group consisting of B, Al, Ga, In, and rare earth elements; M¹¹ represents at least one element selected from the group consisting of Si, Ti, Ge, Zr, Sn, Hf, and Pb; M¹² represents at least one element selected from the group consisting of Eu, Ce, Tb, Pr, Nd, Sm, Yb, Ho, Er, Tm, Ni, and Mn; and e, f, g, h, i, and j satisfy 0<e≤0.2, 0≤f≤0.1, f≤e, 0.7≤g≤1.3, 1.5≤h≤2.5, 0.7≤i≤1.3, and 12.9≤j≤15.1.

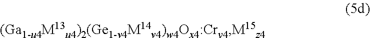

wherein M¹³ represents at least one element selected from the group consisting of Al, Sc, and In; M¹4 represents at least one element selected from the group consisting of Si, Ti, Zr, Sn, and Hf; M¹⁵ represents at least one element selected from the group consisting of Ni, Eu, Fe, Mn, Nd, Tm, Ho, Er, and Yb; and u4, v4, w4, x4, y4, and z4 satisfy 0≤u4≤1.0, 0≤v4≤0.5, 1.0≤w4≤3.0, 5≤x4≤9, 0.005≤y4≤1.0, and 0≤z4≤0.5.

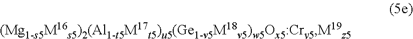

wherein M¹⁶ represents at least one element selected from the group consisting of Ca, Sr, Ba, and Zn; M¹⁷ represents at least one element selected from the group consisting of Ga, Sc, and In; M¹⁸ represents at least one element selected from the group consisting of Si, Ti, Zr, Sn, and Hf; M¹⁹ represents at least one element selected from the group consisting of Ni, Ce, Eu, Fe, Mn, Nd, Tm, Ho, Er, and Yb; and s5, t5, u5, v5, w5, x5, y5, and z5 satisfy 0≤s5≤1.0, 0≤t5≤1.0, 1.5≤u5≤2.5, 0≤v5≤0.5, 3.0≤w5≤6.0, 11.0≤x5≤17.0, 0.005≤y5≤1.0, and 0≤z5≤0.5.

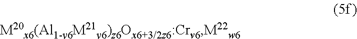

wherein M²⁰ represents at least one element selected from the group consisting of alkaline earth metal elements; M²¹ represents at least one element selected from the group consisting of Group 13 elements excluding Al; M²² represents at least one element selected from the group consisting of Mn, Eu, Ce, Tb, Pr, Nd, Sm, Yb, Ho, Er, and Tm; and v6, w6, x6, y6, and z6 satisfy 0.004≤v6≤0.8, 0≤w6≤0.4, 0.004≤v6+w6≤0.8, 1.0≤x6≤4.0, 0≤y6≤0.7, and 4.0≤z6≤1.50.

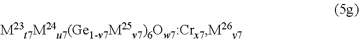

wherein M²³ represents at least one element selected from the group consisting of Li, Na, K, Rb, and Cs; M²4 represents at least one element selected from the group consisting of Ca, Sr, Mg, Ba, and Zn; M²⁵ represents at least one element selected from the group consisting of Si, Ti, Zr, Sn, Hf, and Pb; M²⁶ represents at least one element selected from the group consisting of Eu, Ce, Tb, Pr, Nd, Sm, Yb, Ho, Er, Tm, Ni, and Mn; and t7, u7, v7, w7, x7, and y7 satisfy 1.5≤t7≤2.5, 0.7≤u7≤1.3, 0≤v7≤0.4, 12.9≤w7≤15.1, 0≤x7≤0.2, 0≤y7≤0.10, and y7≤x7.

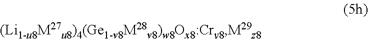

wherein M²⁷ represents at least one element selected from the group consisting of Na, K, Rb, and Cs; M²⁸ represents at least one element selected from the group consisting of Si, Ti, Zr, Sn, and Hf; M²⁹ represents at least one element selected from the group consisting of Ni, Eu, Fe, Mn, Nd, Tm, Ho, Er, and Yb; and u8, v8, w8, x8, y8, and z8 satisfy 0≤u8≤0.3, 0≤v8≤0.5, 3.5≤w8≤15, 9≤x8≤32, 0.005≤y8<1.0, and 0≤z8≤0.5.

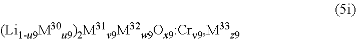

wherein M³⁰ represents at least one element selected from the group consisting of Na, K, Rb, and Cs; M³¹ represents at least one element selected from the group consisting of Mg, Ca, Sr, Ba, and Zn; M³² represents at least one element selected from the group consisting of Si, Ge, Ti, Zr, Sn, and Hf; M³³ represents at least one element selected from the group consisting of Ni, Eu, Fe, Mn, Nd, Tm, Ho, Er, and Yb; and u9, v9, w9, x9, y9, and z9 satisfy 0≤u9≤1.0, 0.8≤v9≤3.0, 1.8≤w9≤6, 5.4x9≤16, 0.005≤y9≤1.0, and 0≤z9≤0.5.

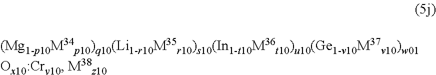

wherein M³⁴ represents at least one element selected from the group consisting of Ca, Sr, Ba, and Zn; M³⁵ represents at least one element selected from the group consisting of Na, K, Rb, and Cs; M³⁶ represents at least one element selected from the group consisting of Al, Ga, and Sc; M³⁷ represents at least one element selected from the group consisting of Si, Ti, Zr, Sn, and Hf; M³⁸ represents at least one element selected from the group consisting of Ni, Ce, Eu, Fe, Mn, Nd, Tm, Ho, Er, and Yb; and p10, q10, r10, s10, t10, u10, v10, w10, x10, y10, and z10 satisfy 0≤p10≤1.0 0.1≤q10≤0.9, 0≤r10≤1.0 0.05≤s10≤0.45, 0≤t10≤0.5, 0.05≤u10≤0.45, 0≤v10≤10, 0.8w10≤1.3, 2.6≤x10≤3.6, 0.02≤y10≤0.5, 0≤z10≤0.3, and 0.9≤q10+s10+u10≤1.2.

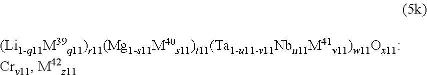

wherein M³⁹ represents at least one element selected from the group consisting of Na, K, Rb, and Cs; M⁴⁰ represents at least one element selected from the group consisting of Zn, Ca, Sr, and Ba; M⁴¹ represents at least one element selected from the group consisting of P, V, Sb, and Bi; M⁴² represents at least one element selected from the group consisting of Ni, Ce, Eu, Fe, Mn, Nd, Tm, Ho, Er, and Yb; and q11, r11, s11, t11, u11, v11, w11, x11, y11, and z11 satisfy 0≤q11≤0.5, 0.5≤5r11≤3.5, 0≤5s11≤0.5, 1.8≤t11≤3.2, 0≤u11≤51.0, 0≤5v11≤0.3, 0≤u11+v11≤1.0, 0.8≤w11≤1.2, 5.1≤x11≤6.9, 0.002≤y11≤0.5, and 0≤z11≤0.3.

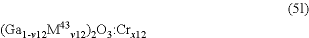

wherein M⁴³ represents at least one element selected from the group consisting of Al, In, and rare earth elements; and v12 and x12 satisfy 0≤v12 K 1.0 and 0.02≤x12<0.3.

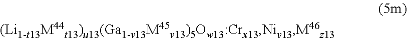

wherein M⁴⁴ represents at least one element selected from the group consisting of Na, K, Rb, and Cs; M⁴⁵ represents at least one element selected from the group consisting of B, Al, In, and rare earth elements; M⁴⁶ represents at least one element selected from the group consisting of Si, Ge, Sn, Ti, Zr, Hf, Bi, V, Nd, and Ta; and t13, u13, v13, w13, x13, y13, and z13 satisfy 0≤t13≤1.0, 0.7≤u13≤1.6, 0≤v13≤1.0, 7.85≤w13≤11.5, 0.05≤x13≤1.2, 0≤y13≤0.5, 0.25≤x13+y13≤1.2, x13>y13, and 0≤z13≤0.5.

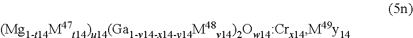

wherein M⁴⁷ represents at least one element selected from the group consisting of Ca, Sr, Ba, Ni, and Zn; M⁴⁸ represents at least one element selected from the group consisting of B, Al, In, and Sc; M⁴⁹ represents at least one element selected from the group consisting of Eu, Ce, Tb, Pr, Nd, Sm, Yb, Ho, Er, Tm, and Mn; and t14, u14, v14, w14, x14, and y14 satisfy 0≤t14≤0.8, 0.7≤u14<1.3, 0≤v14≤0.8, 3.7≤w14≤4.3, 0.02≤x14≤0.3, 0≤y14≤0.2, and x14>y14.

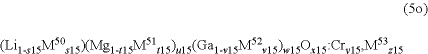

wherein M⁵⁰ represents at least one element selected from the group consisting of Na, K, Rb, and Cs; M⁵¹ represents at least one element selected from the group consisting of Ca, Sr, Ba, and Zn; M⁵² represents at least one element selected from the group consisting of Al and Sc; M⁵³ represents at least one element selected from the group consisting of Ni, Ce, Eu, Fe, Mn, Nd, Tm, Ho, Er, and Yb; s15, t15, u15, v15, w15, and x15 satisfy 0≤s15≤0.5, 0≤t15≤1.0, 0.03≤u15≤10, 0≤v15≤1.0, 5.1≤w15≤25, 0.005≤u15/w15≤0.4, 8.2≤x15≤48; and when a molar ratio of Li is 1 or a total molar ratio of Li and M⁵⁰ is 1, y15 and z15 satisfy 0.02≤y15≤0.5, 0≤z15≤0.3, and y15>z15 relative to the molar ratio of Li or the total molar ratio of Li and M⁵⁰.

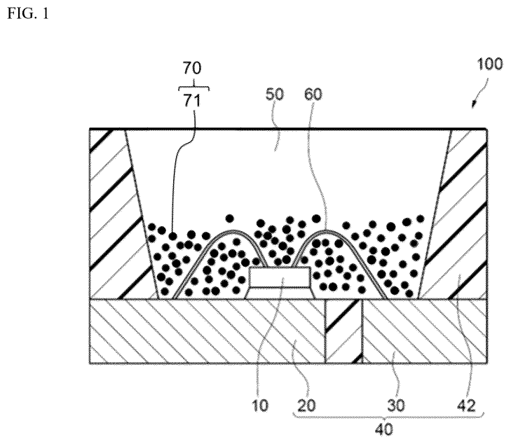

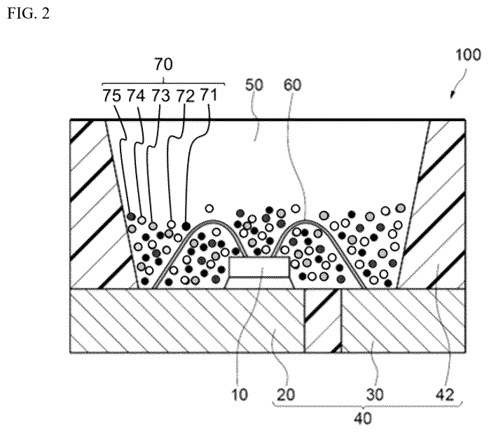

An example of the light emitting device will be described below with reference to the drawings. FIG. 1 is a schematic cross-sectional view showing an exemplary light emitting device according to a first embodiment of the present disclosure. FIG. 2 is a schematic cross-sectional view showing another exemplary light emitting device according to the first embodiment of the present disclosure.

As shown in FIG. 1, a light emitting device 100 includes a molded body 40 defining a recessed portion, a light emitting element 10 serving as an excitation light source, and a wavelength conversion member 50 that covers the light emitting element 10. The molded body 40 is formed by integrally molding together a first lead 20, a second lead 30, and a resin portion 42 containing a thermoplastic resin or a thermosetting resin. In the molded body 40, at least the first lead 20 and the second lead 30 constitute a surface defining the bottom of the recessed portion, and at least the resin portion 42 constitutes the lateral surface(s) defining lateral surfaces of the recessed portion. The light emitting element 10 is mounted on the surface defining the bottom of the recessed portion of the molded body 40. The light emitting element 10 has positive and negative electrodes, and the positive and negative electrodes are respectively electrically connected to the first lead 20 and the second lead 30 via wires 60. The light emitting element 10 is covered by the wavelength conversion member 50. The wavelength conversion member 50 preferably includes a phosphor 70 that converts the wavelength of light emitted from the light emitting element 10, and a light-transmissive material. The phosphor 70 essentially contains a first phosphor 71 containing an oxide phosphor. The oxide phosphor contained in the first phosphor 71 contains an oxide phosphor having a composition represented by the formula (1). The phosphor 70 may contain a phosphor having a composition different from that of the first phosphor 71. As shown in FIG. 2, the phosphor 70 preferably contains at least one phosphor selected from the group consisting of the second phosphor 72, the third phosphor 73, the fourth phosphor 74, and the fifth phosphor 75 described above, and may contain two or more types of these. The phosphor 70 essentially contains the first phosphor 71, and may contain the second phosphor 72, the third phosphor 73, the fourth phosphor 74, and the fifth phosphor 75. The wavelength conversion member 50 also functions as a member for protecting, for example, the light emitting element 10, the wires 60, and the phosphor 70 from the external environment. The light emitting device 100 emits light upon receiving external electric power through the first lead 20 and the second lead 30.

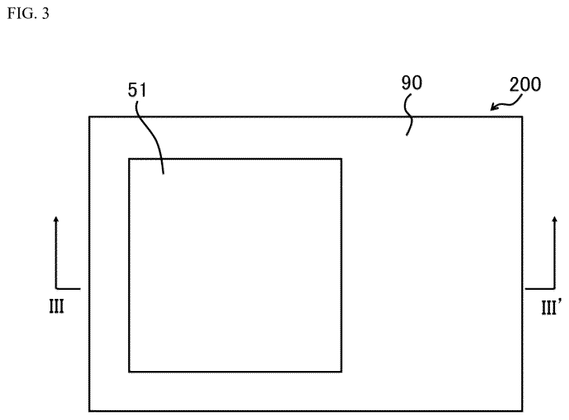

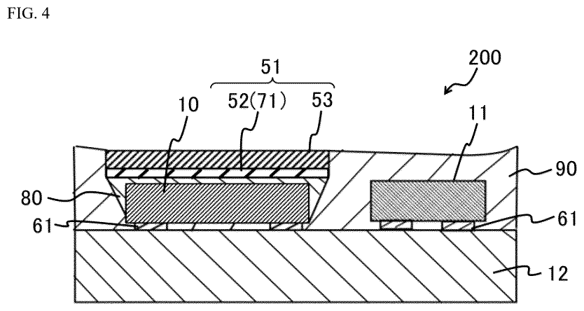

FIGS. 3 and 4 show an exemplary light emitting device according to a second embodiment of the present disclosure. FIG. 3 is a schematic plan view of a light emitting device 200. FIG. 4 is a schematic cross-sectional view of the III-III′ line of the light emitting device 200 shown in FIG. 3. The light emitting device 200 includes a light emitting element 10 having a light emission peak wavelength in a range of 365 nm or more and 650 nm or less, and a wavelength conversion member 51. The wavelength conversion member 51 includes a wavelength conversion body 52 containing a first phosphor 71 that is adapted to be excited by light emitted from the light emitting element 10 and to emit light, and a light-transmissive body 53 disposed on the light emitting surface side of the wavelength conversion body 52. The light emitting element 10 is flip chip mounted on a substrate 12 via bumps that are conductive members 61. The wavelength conversion body 52 of the wavelength conversion member 51 is disposed on the light emitting surface of the light emitting element 10 via an adhesive layer 80. The lateral surface(s) of the light emitting element 10 and the lateral surface(s) of the wavelength conversion member 51 are covered with a covering member 90 that reflects light. The wavelength conversion body 52 contains a phosphor adapted to be excited by light emitted from the light emitting element 10. The phosphor contained in the wavelength conversion body 52 essentially contains a first phosphor 71 containing an oxide phosphor. The oxide phosphor contained in the first phosphor 71 contains an oxide phosphor having a composition represented by the formula (1). The phosphor may contain a phosphor having a composition different from that of the first phosphor 71. The wavelength conversion body 52 may contain at least one selected from the group consisting of the second phosphor, the third phosphor, the fourth phosphor, and the fifth phosphor. The light emitting element 10 receives electric power from the outside of the light emitting device 200 via the wiring and the conductive members 61 formed on the substrate 12, thereby enabling the light emitting device 200 to emit light. The light emitting device 200 may include a semiconductor element 11 such as a protective element for preventing the light emitting element 10 from being broken due to excessive voltage application. The semiconductor element 11 may be mounted on the substrate 12 via the conductive members 61. The covering member 90 is disposed to cover, for example, the semiconductor element 11. Members used in the light emitting device are described below. For the details, for example, the disclosure of Japanese Unexamined Patent Publication No. 2014-112635 may be referenced.

Examples of the light-transmissive material constituting the wavelength conversion body together with the phosphor include at least one selected from the group consisting of resin, glass, and inorganic substances. As the resin, at least one resin selected from the group consisting of a silicone resin, an epoxy resin, a phenol resin, a polycarbonate resin, an acrylic resin, and modified resins thereof can be used. Among these, a silicone resin and a modified silicone resin are preferred because of their good heat and light resistance. The wavelength conversion member may optionally contain a filler, a colorant, and a light diffusing material in addition to the phosphor and the light-transmissive material. Examples of the filler include silicon oxide, barium titanate, titanium oxide, and aluminum oxide.

As the light-transmissive body, a plate-shaped body formed of a light-transmissive material such as glass or resin can be used. Examples of the glass include borosilicate glass and quartz glass. Examples of the resin include a silicone resin and an epoxy resin. When the wavelength conversion member includes a substrate, the substrate is preferably formed of an insulating material that is difficult to transmit light emitted from the light emitting element and external light. Examples of the material of the substrate include ceramics such as aluminum oxide and aluminum nitride, and resins such as a phenol resin, an epoxy resin, a polyimide resin, a bismaleimide triazine resin (BT resin), and a polyphthalamide (PPA) resin. When an adhesive layer is disposed between the light emitting element and the wavelength conversion member, an adhesive constituting the adhesive layer is preferably formed of a material capable of optically connecting the light emitting element and the wavelength conversion member. A material constituting the adhesive layer is preferably at least one resin selected from the group consisting of an epoxy resin, a silicone resin, a phenol resin, and a polyimide resin. The light-transmissive body does not have to be disposed on the wavelength conversion member.

Examples of the semiconductor element optionally disposed in the light emitting device include a transistor for controlling the light emitting element and a protective element for preventing the destruction and the performance degradation of the light emitting element due to excessive voltage application. Examples of the protective element include a Zener diode. When the light emitting device includes a covering member, it is preferable to use an insulating material as the material of the covering member. More specific examples thereof include a phenol resin, an epoxy resin, a bismaleimide triazine resin (BT resin), a polyphthalamide (PPA) resin, and a silicone resin. A colorant, a phosphor, and a filler may be optionally added to the covering member. In the light emitting device, bumps may be used as conductive members. Examples of the material of the bumps include Au and an alloy thereof, and examples of the other conductive member include eutectic solder (Au—Sn), Pb—Sn, and lead-free solder.

An example of the method for producing an exemplary light emitting device according to the first embodiment will be described below. For the details, for example, the disclosure of Japanese Unexamined Patent Publication No. 2010-062272 may be referenced. The method for producing a light emitting device preferably includes a step of providing a molded body, a step of disposing a light emitting element, a step of disposing a composition for forming the wavelength conversion member, and a step of forming a resin package. When using a block of molded body having a plurality of recessed portions, the production method may include, after the step of forming a resin package, a singulating step of separating the block into individual resin packages for respective unit regions.

In the step of providing a molded body, a plurality of leads and a thermosetting resin or a thermoplastic resin are integrally molded together to provide a molded body having a recessed portion with surfaces defining lateral surface(s) and a bottom of the recessed portion. The molded body may be formed of a block including a plurality of recessed portions.

In the step of disposing a light emitting element, a light emitting element is disposed on the surface defining the bottom of the recessed portion of the molded body, and the positive and negative electrodes of the light emitting element are connected to the first lead and the second lead, respectively, by wires.

In the step of disposing a composition for forming the wavelength conversion member, a composition for forming the wavelength conversion member is disposed in the recessed portion of the molded body.

In the step of forming a resin package, the composition for forming the wavelength conversion member disposed in the recessed portion of the molded body is cured to form a resin package, thereby producing a light emitting device. When using a molded body formed of a block including a plurality of recessed portions, in the singulating step after the step of forming a resin package, the molded body is separated for each resin package in each unit region from the block including a plurality of recessed portions, so that individual light emitting devices are produced. In this manner, the light emitting devices shown in FIGS. 1 and 2 can be produced.

An example of the method for producing an exemplary light emitting device according to the second embodiment will be described. For the details, for example, the disclosure of Japanese Unexamined Patent Publication No. 2014-112635 or Japanese Unexamined Patent Publication No. 2017-117912 may be referenced. The method for producing a light emitting device preferably includes a step of disposing a light emitting element, a step of disposing a semiconductor element that is optionally performed, a step of forming a wavelength conversion member including a wavelength conversion body, a step of adhering a light emitting element and a wavelength conversion member, and a step of forming a covering member.

For example, in the step of disposing a light emitting element, a light emitting element is disposed on a substrate. The light emitting element and a semiconductor element are flip chip mounted, for example, on the substrate. Subsequently, in the step of forming a wavelength conversion member including a wavelength conversion body, a wavelength conversion body may be obtained by forming a plate-shaped, sheet-shaped, or layered wavelength conversion body on a surface of a light-transmissive body by a printing method, an adhesive method, a compression molding method, or an electrodeposition method. For example, in the printing method, a wavelength conversion body composition containing a phosphor and a resin serving as a binder or a solvent can be printed on the surface of the light-transmissive body to form a wavelength conversion member including a wavelength conversion body. Subsequently, in the step of adhering a light emitting element and a wavelength conversion member, the wavelength conversion member is allowed to face the light emitting surface of the light emitting element, and the wavelength conversion member is adhered onto the light emitting element by an adhesive layer. Subsequently, in the step of forming a covering member, the lateral surface(s) of the light emitting element and the lateral surface(s) of the wavelength conversion member are covered with a composition for a covering member. The covering member is configured to reflect light emitted from the light emitting element, and when the light emitting device includes a semiconductor element, it is preferable to form the covering member such that the semiconductor element is embedded by the covering member. In this manner, the light emitting device shown in FIGS. 3 and 4 can be produced.

The method for producing an oxide phosphor includes: providing a raw material mixture that contains a first compound containing Li, a ninth compound containing Cr, and at least one compound selected from the group consisting of a third compound containing Zn, a fourth compound containing an element M², a fifth compound containing Ga, a sixth compound containing an element M³, a seventh compound containing Ge, and an eighth compound containing an element M⁴, and that may optionally contain a second compound containing an element M¹ and a tenth compound containing an element M⁵; and heat-treating the raw material mixture at a temperature of 1,200° C. or higher and 1,700° C. or lower in an oxygen-containing atmosphere to obtain an oxide phosphor.

The raw material mixture preferably contains a ninth compound containing Cr such that, when a molar ratio of Li or a total molar ratio of Li and the element M¹ is 2 in 1 mol of the composition of the oxide phosphor obtained, a molar ratio of Cr is 0.02 or more and 0.5 or less.

In the raw material mixture, the compounds containing the respective elements are preferably mixed such that the oxide phosphor obtained satisfies the composition represented by the formula (1).

The raw materials, i.e., the first compound containing Li, the second compound containing an element M¹, the third compound containing Zn, the fourth compound containing an element M², the fifth compound containing Ga, the sixth compound containing an element M³, the seventh compound containing Ge, the eighth compound containing an element M⁴, the ninth compound containing Cr, and the tenth compound containing an element M⁵, are preferably at least one selected from the group consisting of oxides, carbonates, chlorides, and hydrates thereof. At least one of the first to tenth compounds is preferably an oxide, and the ninth compound containing Cr is preferably an oxide.

The raw materials, i.e., the first compound containing Li; the ninth compound containing Cr; at least one compound selected from the group consisting of the third compound containing Zn, the fourth compound containing an element M², the fifth compound containing Ga, the sixth compound containing an element M³, the seventh compound containing Ge, and the eighth compound containing an element M⁴; the second compound containing an element M¹ that may be optionally contained; and the tenth compound containing an element M⁵ that may be optionally contained, may be mixed using a mixing machine to obtain a raw material mixture. As the mixing machine, for example, a ball mill, a vibration mill, a roll mill, and a jet mill, which are commonly used in industry, can be used.

The raw material mixture may contain a flux. When the raw material mixture contains a flux, the reaction between the raw materials is promoted more and the solid-phase reaction proceeds more uniformly, so that a phosphor having a large particle diameter and good light emission characteristics can be obtained. When the temperature of the heat treatment for obtaining a phosphor is the same as or similar to the temperature at which the liquid phase of the compound used as the flux is formed, the flux facilitates the reaction between the raw materials. As the flux, a halide containing at least one element selected from the group consisting of rare earth elements, alkaline earth metal elements, and alkali metal elements can be used. Among halides, fluoride can be used as the flux. In the case where the element contained in the flux is the same as the at least part of the elements constituting the oxide phosphor, the flux can be added as part of the raw materials of the oxide phosphor having a desired composition such that the composition of the oxide phosphor has the desired composition, or the flux can be added as a further addition after mixing the raw materials to achieve the desired composition.

The raw material mixture can be positioned in a crucible or a boat formed of a material such as graphite or other carbon, boron nitride (BN), alumina (Al₂O₃), tungsten (W), or molybdenum (Mo), and heat-treated in a furnace.

The heat treatment is preferably performed in an atmosphere containing oxygen. Any appropriate content of oxygen can be contained in the atmosphere. The content of oxygen in the atmosphere containing oxygen is preferably 5% by volume or more, more preferably 10% by volume or more, and even more preferably 15% by volume or more. The heat treatment is preferably performed in an air atmosphere (oxygen content of 20% by volume or more). If the atmosphere does not contain oxygen, e.g., if an oxygen content is less than 1% by volume, there may be a case in which an oxide phosphor having a desired composition is not obtained.

The temperature of the heat treatment is 1,200° C. or higher and 1,700° C. or lower, preferably 1,250° C. or higher and 1,650° C. or lower, and more preferably 1,260° C. or higher and 1,600° C. or lower. When the temperature of the heat treatment is 1,200° C. or higher and 1,700° C. or lower, the oxide phosphor can be inhibited from decomposition by heat, and thus can have a desired composition and a stable crystal structure.

In the heat treatment, a maintaining time at a predetermined temperature may be set. The maintaining time may be, for example, 0.5 hour or more and 48 hours or less, may be 1 hour or more and 40 hours or less, or may be 2 hours or more and 30 hours or less. By setting the maintaining time in the range of 0.5 hour or more and 48 hours or less, the crystal growth can be facilitated.

The pressure in the heat treatment atmosphere may be standard atmospheric pressure (0.101 MPa) and may be 0.101 MPa or more; and the heat treatment may be performed in a pressurized atmosphere range of 0.11 MPa or more and 200 MPa or less. In the heat-treated product obtained by the heat treatment, the crystal structure is more easily decomposed at a higher heat treatment temperature, but the decomposition of the crystal structure can be inhibited in a pressurized atmosphere.

The heat treatment time can be appropriately selected depending on the heat treatment temperature and the pressure of the atmosphere during the heat treatment and is preferably 0.5 hour or more and 20 hours or less. Even in the case of performing two or more stages of heat treatment, the time for one heat treatment is preferably 0.5 hour or more and 20 hours or less. With the heat treatment time of 0.5 hour or more and 20 hours or less, the decomposition of the heat-treated product obtained is inhibited, and a phosphor having a stable crystal structure and a desired light emission intensity can be obtained. In addition, the production cost can be reduced, and the production time can be relatively shortened. The heat treatment time is more preferably 1 hour or more and 10 hours or less, even more preferably 1.5 hours or more and 9 hours or less.

The heat-treated product obtained by the heat treatment may be subjected to post-treatments such as pulverization, dispersion, solid-liquid separation, and drying. The solid-liquid separation may be performed by a method used industrially, such as filtration, suction filtration, pressure filtration, centrifugal separation, and decantation. The drying may be performed with an apparatus used industrially, such as a vacuum dryer, a hot air dryer, a conical dryer, or a rotary evaporator.

### EXAMPLES

The present disclosure will be more specifically described with reference to the following Examples. The present disclosure is not limited to the following Examples.

### Example 1

Raw materials were weighed as 1.1 g of Li₂CO₃, 1.2 g of ZnO, 11.3 g of Ga₂O₃, 1.6 g of GeO₂, and 0.06 g of Cr₂O₃ (target composition of Li₂ZnGa₈GeO₁₆:Cr_{0.026}), and the raw materials were mixed using an agate mortar and an agate pestle for approximately 10 minutes to provide a raw material mixture. In the present specification, in the target composition or the composition represented by the formula (1), the molar ratio of an element without a numerical value is 1. The resulting raw material mixture was placed in an alumina crucible and heat-treated at 1,260° C. for 6 hours in an air atmosphere (20% by volume of oxygen) with standard atmospheric pressure (0.101 MPa).

After the heat treatment, the resulting heat-treated product was pulverized to obtain an oxide phosphor according to Example 1 having the molar ratios the same as or similar to those in the target composition.

The oxide phosphor according to Example 1 had the composition shown in Table 1 and had the composition represented by the formula (1). In the oxide phosphor according to Example 1, the parameter q in the formula (1) was 0 (q=0), the parameter r was 0 (r=0), the parameter s was 1.0 (s=1.0), the parameter t was 0 (t=0), the parameter u was 8 (u=8), the parameter v was 0 (v=0), the parameter w was 1.0 (w=1.0), the parameter x was 16 (x=16), the parameter y was 0.026 (y=0.026), and the parameter z was 0 (z=0).

### Example 2

Raw materials were weighed as 1.1 g of Li₂CO₃, 1.2 g of ZnO, 11.3 g of Ga₂O₃, 1.6 g of GeO₂, and 0.12 g of Cr₂O₃ to provide a raw material mixture (target composition of Li₂ZnGa₈GeO16:Cr_{0.053}), and the other processes were performed in the molar ratios the same as or similar to Example 1 to obtain an oxide phosphor according to Example 2 having the molar ratios the same as or similar to those in the target composition.

The oxide phosphor according to Example 2 had the composition shown in Table 1 and had the composition represented by the formula (1). In the oxide phosphor according to Example 2, the parameter q in the formula (1) was 0 (q=0), the parameter r was 0 (r=0), the parameter s was 1.0 (s=1.0), the parameter t was 0 (t=0), the parameter u was 8 (u=8), the parameter v was 0 (v=0), the parameter w was 1.0 (w=1.0), the parameter x was 16 (x=16), the parameter y was 0.053 (y=0.053), and the parameter z was 0 (z=0).

### Example 3

Raw materials were weighed as 1.1 g of Li₂CO₃, 1.2 g of ZnO, 11.3 g of Ga₂O₃, 1.6 g of GeO₂, and 0.18 g of Cr₂O₃ to provide a raw material mixture (target composition of Li₂ZnGa₈GeO16:Cr_{0.079}), and the other processes were performed in the molar ratios the same as or similar to Example 1 to obtain an oxide phosphor according to Example 3 having the molar ratios the same as or similar to those in the target composition.

The oxide phosphor according to Example 3 had the composition shown in Table 1 and had the composition represented by the formula (1). In the oxide phosphor according to Example 3, the parameter q in the formula (1) was 0 (q=0), the parameter r was 0 (r=0), the parameter s was 1.0 (s=1.0), the parameter t was 0 (t=0), the parameter u was 8 (u=8), the parameter v was 0 (v=0), the parameter w was 1.0 (w=1.0), the parameter x was 16 (x=16), the parameter y was 0.079 (y=0.079), and the parameter z was 0 (z=0).

### Example 4

Raw materials were weighed as 1.1 g of Li₂CO₃, 1.2 g of ZnO, 11.3 g of Ga₂O₃, 1.6 g of GeO₂, and 0.27 g of Cr₂O₃ to provide a raw material mixture (target composition of Li₂ZnGa₈GeO16:Cr_{0.12}), and the other processes were performed in the molar ratios the same as or similar to Example 1 to obtain an oxide phosphor according to Example 4 having the molar ratios the same as or similar to those in the target composition.

The oxide phosphor according to Example 4 had the composition shown in Table 1 and had the composition represented by the formula (1). In the oxide phosphor according to Example 4, the parameter q in the formula (1) was 0 (q=0), the parameter r was 0 (r=0), the parameter s was 1.0 (s=1.0), the parameter t was 0 (t=0), the parameter u was 8 (u=8), the parameter v was 0 (v=0), the parameter w was 1.0 (w=1.0), the parameter x was 16 (x=16), the parameter y was 0.12 (y=0.12), and the parameter z was 0 (z=0).

### Example 5

Raw materials were weighed as 1.1 g of Li₂CO₃, 0.6 g of MgO, 11.3 g of Ga₂O₃, 1.6 g of GeO₂, and 0.18 g of Cr₂O₃ to provide a raw material mixture (target composition of Li₂MgGa₈GeO16:Cr_{0.079}), and the other processes were performed in the molar ratios the same as or similar to Example 1 to obtain an oxide phosphor according to Example 5 having the molar ratios the same as or similar to those in the target composition.

The oxide phosphor according to Example 5 had the composition shown in Table 1 and had the composition represented by the formula (1). In the oxide phosphor according to Example 5, the parameter q in the formula (1) was 0 (q=0), the element M² was Mg, the parameter r was 1.0 (r=1.0), the parameter s was 1.0 (s=1.0), the parameter t was 0 (t=0), the parameter u was 8 (u=8), the parameter v was 0 (v=0), the parameter w was 1.0 (w=1.0), the parameter x was 16 (x=16), the parameter y was 0.079 (y=0.079), and the parameter z was 0 (z=0).

### Example 6

Raw materials were weighed as 1.1 g of Li₂CO₃, 0.6 g of MgO, 11.3 g of Ga₂O₃, 0.92 g of SiO₂, and 0.18 g of Cr₂O₃ to provide a raw material mixture (target composition of Li₂MgGa₈SiO₁₆:Cr_{0.079}), and the other processes were performed in the molar ratios the same as or similar to Example 1 to obtain an oxide phosphor according to Example 6 having the molar ratios the same as or similar to those in the target composition.

The oxide phosphor according to Example 6 had the composition shown in Table 1 and had the composition represented by the formula (1). In the oxide phosphor according to Example 6, the parameter q in the formula (1) was 0 (q=0), the element M² was Mg, the parameter r was 1.0 (r=1.0), the parameter s was 1.0 (s=1.0), the parameter t was 0 (t=0), the parameter u was 8 (u=8), the element M⁴ was Si, the parameter v was 1.0 (v=1.0), the parameter w was 1.0 (w=1.0), the parameter x was 16 (x=16), the parameter y was 0.079 (y=0.079), and the parameter z was 0 (z=0).

### Example 7

Raw materials were weighed as 1.1 g of Li₂CO₃, 0.6 g of MgO, 5.7 g of Ga₂O₃, 3.1 g of Al₂O₃, 0.92 g of SiO₂, and 0.12 g of Cr₂O₃ to provide a raw material mixture (target composition of Li₂Mg(Ga_{0.5}Al_{0.5})₈SiO₁₆:Cr_{0.053}), and the other processes were performed in the molar ratios the same as or similar to Example 1 to obtain an oxide phosphor according to Example 7 having the molar ratios the same as or similar to those in the target composition.

The oxide phosphor according to Example 7 had the composition shown in Table 1 and had the composition represented by the formula (1). In the oxide phosphor according to Example 7, the parameter q in the formula (1) was 0 (q=0), the element M² was Mg, the parameter r was 1.0 (r=1.0), the parameter s was 1.0 (s=1.0), the element M³ was Al, the parameter t was 0.5 (t=0.5), the parameter u was 8 (u=8), the element M⁴ was Si, the parameter v was 1.0 (v=1.0), the parameter w was 1.0 (w=1.0), the parameter x was 16 (x=16), the parameter y was 0.053 (y=0.053), and the parameter z was 0 (z=0).

### Example 8

Raw materials were weighed as 1.1 g of Li₂CO₃, 0.6 g of MgO, 6.2 g of Al₂O₃, 0.92 g of SiO₂, and 0.12 g of Cr₂O₃ to provide a raw material mixture (target composition of Li₂MgAl₈SiO₁₆:Cr_{0.053}), and the other processes were performed in the molar ratios the same as or similar to Example 1 to obtain an oxide phosphor according to Example 8 having the molar ratios the same as or similar to those in the target composition.

The oxide phosphor according to Example 8 had the composition shown in Table 1 and had the composition represented by the formula (1). In the oxide phosphor according to Example 8, the parameter q in the formula (1) was 0 (q=0), the element M² was Mg, the parameter r was 1.0 (r=1.0), the parameter s was 1.0 (s=1.0), the element M³ was Al, the parameter t was 1.0 (t=1.0), the parameter u was 8 (u=8), the element M⁴ was Si, the parameter v was 1.0 (v=1.0), the parameter w was 1.0 (w=1.0), the parameter x was 16 (x=16), the parameter y was 0.053 (y=0.053), and the parameter z was 0 (z=0).

### Example 9

Raw materials were weighed as 1.1 g of Li₂CO₃, 1.2 g of ZnO, 11.3 g of Ga₂O₃, 2.4 g of GeO₂, and 0.18 g of Cr₂O₃ to provide a raw material mixture (target composition of Li₂ZnGa₈Ge_{1.5}O₁₇:Cr_{0.079}), and the other processes were performed in the molar ratios the same as or similar to Example 1 to obtain an oxide phosphor according to Example 9 having the molar ratios the same as or similar to those in the target composition.

The oxide phosphor according to Example 9 had the composition shown in Table 1 and had the composition represented by the formula (1). In the oxide phosphor according to Example 9, the parameter q in the formula (1) was 0 (q=0), the parameter r was 0 (r=0), the parameter s was 1.0 (s=1.0), the parameter t was 0 (t=0), the parameter u was 8 (u=8), the parameter v was 0 (v=0), the parameter w was 1.5 (w=1.5), the parameter x was 17 (x=17), the parameter y was 0.079 (y=0.079), and the parameter z was 0 (z=0).

### Example 10

Raw materials were weighed as 1.1 g of Li₂CO₃, 1.2 g of ZnO, 11.3 g of Ga₂O₃, 3.2 g of GeO₂, and 0.18 g of Cr₂O₃ to provide a raw material mixture (target composition of Li₂ZnGa₈Ge₂O₁₈:Cr_{0.079}), and the other processes were performed in the molar ratios the same as or similar to Example 1 to obtain an oxide phosphor according to Example 10 having the molar ratios the same as or similar to those in the target composition.

The oxide phosphor according to Example 10 had the composition shown in Table 1 and had the composition represented by the formula (1). In the oxide phosphor according to Example 10, the parameter q in the formula (1) was 0 (q=0), the parameter r was 0 (r=0), the parameter s was 1.0 (s=1.0), the parameter t was 0 (t=0), the parameter u was 8 (u=8), the parameter v was 0 (v=0), the parameter w was 2.0 (w=2.0), the parameter x was 18 (x=18), the parameter y was 0.079 (y=0.079), and the parameter z was 0 (z=0).

### Example 11

Raw materials were weighed as 1.1 g of Li₂CO₃, 1.2 g of ZnO, 11.3 g of Ga₂O₃, 3.2 g of GeO₂, and 0.27 g of Cr₂O₃ to provide a raw material mixture (target composition of Li₂ZnGa₈Ge₂O₁₈:Cr_{0.12}), and the other processes were performed in the molar ratios the same as or similar to Example 1 to obtain an oxide phosphor according to Example 11 having the molar ratios the same as or similar to those in the target composition.

The oxide phosphor according to Example 11 had the composition shown in Table 1 and had the composition represented by the formula (1). In the oxide phosphor according to Example 11, the parameter q in the formula (1) was 0 (q=0), the parameter r was 0 (r=0), the parameter s was 1.0 (s=1.0), the parameter t was 0 (t=0), the parameter u was 8 (u=8), the parameter v was 0 (v=0), the parameter w was 2.0 (w=2.0), the parameter x was 18 (x=18), the parameter y was 0.12 (y=0.12), and the parameter z was 0 (z=0).

### Example 12

Raw materials were weighed as 1.1 g of Li₂CO₃, 1.2 g of ZnO, 11.3 g of Ga₂O₃, 3.2 g of GeO₂, and 0.36 g of Cr₂O₃ to provide a raw material mixture (target composition of Li₂ZnGa₈Ge₂O₁₈:Cr_{0.16}), and the other processes were performed in the molar ratios the same as or similar to Example 1 to obtain an oxide phosphor according to Example 12 having the molar ratios the same as or similar to those in the target composition.

The oxide phosphor according to Example 12 had the composition shown in Table 1 and had the composition represented by the formula (1). In the oxide phosphor according to Example 12, the parameter q in the formula (1) was 0 (q=0), the parameter r was 0 (r=0), the parameter s was 1.0 (s=1.0), the parameter t was 0 (t=0), the parameter u was 8 (u=8), the parameter v was 0 (v=0), the parameter w was 2.0 (w=2.0), the parameter x was 18 (x=18), the parameter y was 0.16 (y=0.16), and the parameter z was 0 (z=0).

### Example 13

Raw materials were weighed as 1.1 g of Li₂CO₃, 1.2 g of ZnO, 11.3 g of Ga₂O₃, 4.8 g of GeO₂, and 0.18 g of Cr₂O₃ to provide a raw material mixture (target composition of Li₂ZnGa₈Ge₃O₂₀:Cr_{0.079}), and the other processes were performed in the molar ratios the same as or similar to Example 1 to obtain an oxide phosphor according to Example 13 having the molar ratios the same as or similar to those in the target composition.

The oxide phosphor according to Example 13 had the composition shown in Table 1 and had the composition represented by the formula (1). In the oxide phosphor according to Example 13, the parameter q in the formula (1) was 0 (q=0), the parameter r was 0 (r=0), the parameter s was 1.0 (s=1.0), the parameter t was 0 (t=0), the parameter u was 8 (u=8), the parameter v was 0 (v=0), the parameter w was 3.0 (w=3.0), the parameter x was 20 (x=20), the parameter y was 0.079 (y=0.079), and the parameter z was 0 (z=0).

### Example 14

Raw materials were weighed as 1.1 g of Li₂CO₃, 2.4 g of ZnO, 11.3 g of Ga₂O₃, 3.2 g of GeO₂, and 0.18 g of Cr₂O₃ to provide a raw material mixture (target composition of Li₂Zn₂Ga₈Ge₂O₁₉:Cr_{0.079}), and the other processes were performed in the molar ratios the same as or similar to Example 1 to obtain an oxide phosphor according to Example 14 having the molar ratios the same as or similar to those in the target composition.

The oxide phosphor according to Example 14 had the composition shown in Table 1 and had the composition represented by the formula (1). In the oxide phosphor according to Example 14, the parameter q in the formula (1) was 0 (q=0), the parameter r was 0 (r=0), the parameter s was 2.0 (s=2.0), the parameter t was 0 (t=0), the parameter u was 8 (u=8), the parameter v was 0 (v=0), the parameter w was 2.0 (w=2.0), the parameter x was 19 (x=19), the parameter y was 0.079 (y=0.079), and the parameter z was 0 (z=0).

### Example 15

Raw materials were weighed as 1.1 g of Li₂CO₃, 1.2 g of ZnO, 5.7 g of Ga₂O₃, 3.2 g of GeO₂, 3.1 g of Al₂O₃, and 0.30 g of Cr₂O₃ to provide a raw material mixture (target composition of Li₂Zn(Ga_{0.5}Al_{0.5})₈Ge₂O₁₈:Cr_{0.13}), and the other processes were performed in the molar ratios the same as or similar to Example 1 to obtain an oxide phosphor according to Example 15 having the molar ratios the same as or similar to those in the target composition.

The oxide phosphor according to Example 15 had the composition shown in Table 1 and had the composition represented by the formula (1). In the oxide phosphor according to Example 15, the parameter q in the formula (1) was 0 (q=0), the parameter r was 0 (r=0), the parameter s was 1.0 (s=1.0), the element M³ was Al, the parameter t was 0.5 (t=0.5), the parameter u was 8 (u=8), the parameter v was 0 (v=0), the parameter w was 2.0 (w=2.0), the parameter x was 18 (x=18), the parameter y was 0.13 (y=0.13), and the parameter z was 0 (z=0).

### Example 16

Raw materials were weighed as 1.1 g of Li₂CO₃, 11.3 g of Ga₂O₃, 1.6 g of GeO₂, and 0.18 g of Cr₂O₃ to provide a raw material mixture (target composition of Li₂Ga₈GeO₅:Cro_{0.079}), and the other processes were performed in the molar ratios the same as or similar to Example 1 to obtain an oxide phosphor according to Example 16 having the molar ratios the same as or similar to those in the target composition.

The oxide phosphor according to Example 16 had the composition shown in Table 1 and had the composition represented by the formula (1). In the oxide phosphor according to Example 16, the parameter q in the formula (1) was 0 (q=0), the parameter r was 0 (r=0), the parameter s was 0 (s=0), the parameter t was 0 (t=0), the parameter u was 8 (u=8), the parameter v was 0 (v=0), the parameter w was 1.0 (w=1.0), the parameter x was 15 (x=15), the parameter y was 0.079 (y=0.079), and the parameter z was 0 (z=0).

### Example 17

Raw materials were weighed as 1.1 g of Li₂CO₃, 11.3 g of Ga₂O₃, 1.6 g of GeO₂, and 0.36 g of Cr₂O₃ to provide a raw material mixture (target composition of Li₂Ga₈GeO₁₅:Cr_{0.16}), and the other processes were performed in the molar ratios the same as or similar to Example 1 to obtain an oxide phosphor according to Example 17 having the molar ratios the same as or similar to those in the target composition.

The oxide phosphor according to Example 17 had the composition shown in Table 1 and had the composition represented by the formula (1). In the oxide phosphor according to Example 17, the parameter q in the formula (1) was 0 (q=0), the parameter r was 0 (r=0), the parameter s was 0 (s=0), the parameter t was 0 (t=0), the parameter u was 8 (u=8), the parameter v was 0 (v=0), the parameter w was 1.0 (w=1.0), the parameter x was 15 (x=15), the parameter y was 0.16 (y=0.16), and the parameter z was 0 (z=0).

### Example 18

Raw materials were weighed as 1.1 g of Li₂CO₃, 11.3 g of Ga₂O₃, 2.4 g of GeO₂, and 0.18 g of Cr₂O₃ to provide a raw material mixture (target composition of Li₂Ga₈Ge_{1.5}O₁₆:Cr_{0.079}), and the other processes were performed in the molar ratios the same as or similar to Example 1 to obtain an oxide phosphor according to Example 18 having the molar ratios the same as or similar to those in the target composition.

The oxide phosphor according to Example 18 had the composition shown in Table 1 and had the composition represented by the formula (1). In the oxide phosphor according to Example 18, the parameter q in the formula (1) was 0 (q=0), the parameter r was 0 (r=0), the parameter s was 0 (s=0), the parameter t was 0 (t=0), the parameter u was 8 (u=8), the parameter v was 0 (v=0), the parameter w was 1.5 (w=1.5), the parameter x was 16 (x=16), the parameter y was 0.079 (y=0.079), and the parameter z was 0 (z=0).

### Example 19

Raw materials were weighed as 1.1 g of Li₂CO₃, 11.3 g of Ga₂O₃, 0.92 g of SiO₂, and 0.18 g of Cr₂O₃ to provide a raw material mixture (target composition of Li₂Ga₈SiO₁₅:Cr_{0.079}), and the other processes were performed in the molar ratios the same as or similar to Example 1 to obtain an oxide phosphor according to Example 19 having the molar ratios the same as or similar to those in the target composition.

The oxide phosphor according to Example 19 had the composition shown in Table 1 and had the composition represented by the formula (1). In the oxide phosphor according to Example 19, the parameter q in the formula (1) was 0 (q=0), the parameter r was 0 (r=0), the parameter s was 0 (s=0), the parameter t was 0 (t=0), the parameter u was 8 (u=8), the element M⁴ was Si, the parameter v was 1.0 (v=1.0), the parameter w was 1.0 (w=1.0), the parameter x was 15 (x=15), the parameter y was 0.079 (y=0.079), and the parameter z was 0 (z=0).

### Example 20

Raw materials were weighed as 1.1 g of Li₂CO₃, 11.3 g of Ga₂O₃, 1.8 g of SiO₂, and 0.18 g of Cr₂O₃ to provide a raw material mixture (target composition of Li₂Ga₈Si₂O₁₇:Cr_{0.079}), and the other processes were performed in the molar ratios the same as or similar to Example 1 to obtain an oxide phosphor according to Example 20 having the molar ratios the same as or similar to those in the target composition.

The oxide phosphor according to Example 20 had the composition shown in Table 1 and had the composition represented by the formula (1). In the oxide phosphor according to Example 20, the parameter q in the formula (1) was 0 (q=0), the parameter r was 0 (r=0), the parameter s was 0 (s=0), the parameter t was 0 (t=0), the parameter u was 8 (u=8), the element M⁴ was Si, the parameter v was 1.0 (v=1.0), the parameter w was 2.0 (w=2.0), the parameter x was 17 (x=17), the parameter y was 0.079 (y=0.079), and the parameter z was 0 (z=0).

### Comparative Example 1

Raw materials were weighed as 0.74 g of Li₂CO₃, 9.4 g of Ga₂O₃, and 0.26 g of Cr₂O₃ to provide a raw material mixture (target composition of LiGa₅O₈:Cr_{0.17}), and the other processes were performed in the molar ratios the same as or similar to Example 1 to obtain an oxide phosphor according to Comparative Example 1 having the molar ratios the same as or similar to those in the target composition.

The oxide phosphor according to Comparative Example 1 did not have the composition represented by the formula (1) and did not contain at least one element selected from the group consisting of Zn, the element M², the element M³, Ge, and the element M⁴ represented by the composition formula.

The oxide phosphor according to Comparative Example 1 had a composition represented by the formula (a) different from that of the formula (1), and in the formula (a), the parameter aq was 0 (aq=0), the parameter ay was 0.17 (ay=0.17), and the parameter az was 0 (az=0).

### Measurements of Light Emission Spectrum, Light Emission Peak Wavelength, Full Width at Half Maximum (FWHM), and Relative Light Emission Intensity

For the oxide phosphor according to each of Examples and Comparative Example, the light emission spectrum was measured using a quantum efficiency measurement system (QE-2000, manufactured by Otsuka Electronics Co., Ltd.). The light emission peak wavelength of the excitation light of the light emitting element, which is a semiconductor element, used in the quantum efficiency measurement system was 450 nm. From the obtained light emission spectrum of each phosphor, the relative light emission intensity, light emission peak wavelength, and full width at half maximum were determined as light emission characteristics. Specifically, the light emission peak wavelength (nm) in the light emission spectrum of each phosphor and the full width at half maximum (FWHM) (nm) in the light emission spectrum were determined. For the oxide phosphors according to Examples 1 to 20, the relative light emission intensity (%) was determined relative to the light emission intensity at the light emission peak wavelength of the oxide phosphor according to Comparative Example 1 being 100%. The results are shown in Table 1. The light emission spectrum of the oxide phosphor according to each of Examples and Comparison Example is shown in each figure.

TABLE 1

| | | Light emission | Full width at | Relative light |
|---|---|---|---|---|
| | | peak | half maximum | emission |
| | | wavelength | (FWHM) | intensity |
| | Composition | (nm) | (nm) | (%) |
| Example 1 | Li₂ZnGa₈GeO₁₆:Cr_{0.026} | 715 | 70 | 109.3 |
| Example 2 | Li₂ZnGa₈GeO₁₆:Cr_{0.053} | 716 | 90 | 144.3 |
| Example 3 | Li₂ZnGa₈GeO₁₆:Cr_{0.079} | 721 | 115 | 128.6 |
| Example 4 | Li₂ZnGa₈GeO₁₆:Cr_{0.12} | 761 | 170 | 104.4 |
| Example 5 | Li₂MgGa₈GeO₁₆:Cr_{0.079} | 726 | 125 | 117.5 |
| Example 6 | Li₂MgGa₈SiO₁₆:Cr_{0.079} | 724 | 65 | 124.6 |
| Example 7 | Li₂Mg(Ga_{0.5}Al_{0.5})₈SiO₁₆:Cr_{0.053} | 725 | 50 | 119.0 |
| Example 8 | Li₂MgAl₈SiO₁₆:Cr_{0.053} | 698 | 70 | 102.8 |
| Example 9 | Li₂ZnGa₈Ge_{1.5}O₁₇:Cr_{0.079} | 794 | 240 | 127.8 |
| Example 10 | Li₂ZnGa₈Ge₂O₁₈:Cr_{0.079} | 826 | 230 | 115.7 |
| Example 11 | Li₂ZnGa₈Ge₂O₁₈:Cr_{0.12} | 865 | 205 | 121.7 |
| Example 12 | Li₂ZnGa₈Ge₂O₁₈:Cr_{0.16} | 884 | 245 | 100.1 |
| Example 13 | Li₂ZnGa₈Ge₃O₂₀:Cr_{0.079} | 833 | 210 | 108.4 |
| Example 14 | Li₂Zn₂Ga₈Ge₂O₁₉:Cr_{0.079} | 782 | 220 | 113.2 |
| Example 15 | Li₂Zn(Ga_{0.5}Al_{0.5})₈Ge₂O₁₈:Cr_{0.13} | 834 | 240 | 119.0 |
| Example 16 | Li₂Ga₈GeO₁₅:Cr_{0.079} | 834 | 225 | 129.3 |
| Example 17 | Li₂Ga₈GeO₁₅:Cr_{0.16} | 839 | 210 | 108.8 |
| Example 18 | Li₂Ga₈Ge_{1.5}O₁₆:Cr_{0.079} | 826 | 230 | 116.6 |
| Example 19 | Li₂Ga₈SiO₁₅:Cr_{0.079} | 719 | 8 | 123.3 |
| Example 20 | Li₂Ga₈Si₂O₁₇:Cr_{0.079} | 719 | 16 | 125.3 |
| Comparative | LiGa₅O₈:Cr_{0.17} | 720 | 130 | 100.0 |
| Example 1 | | | | |

Each of the oxide phosphors according to Examples 1 to 20 had a composition represented by the formula (1), and thus exhibited a higher relative light emission intensity compared to that of the oxide phosphor according to Comparative Example 1 having a composition different from that represented by the formula (1).

Each of the oxide phosphors according to Examples 1 to 20 had a composition represented by the formula (1), and was thus capable of emitting light having a light emission peak wavelength from red light to near-infrared light, which is 680 nm or more and 900 nm or less, in the light emission spectrum upon irradiation with excitation light.

Each of the oxide phosphors according to Examples 1 to 20 had a composition represented by the formula (1), and thus had a full width at half maximum of 5 nm or more and 250 nm or less in the light emission spectrum.

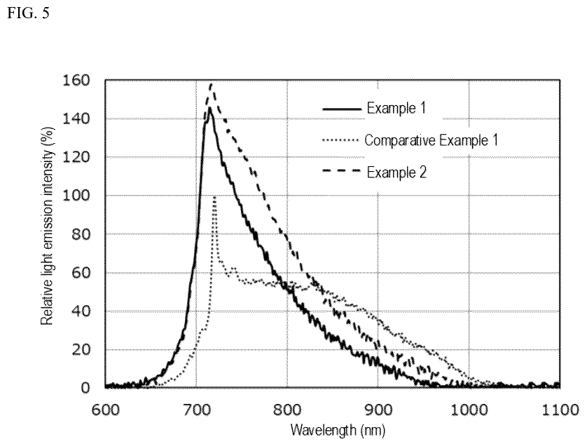

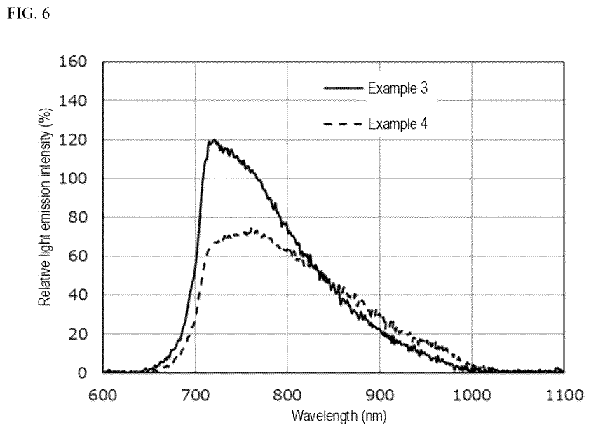

Each of the oxide phosphors according to Examples 1 to 4 had a composition represented by the formula (1) in which Zn was contained, and either Mg was not contained as the element M² or the element M² was not contained, and thus had a full width at half maximum of 40 nm or more and 250 nm or less in the light emission spectrum and a light emission peak wavelength of 700 nm or more and 900 nm or less in the light emission spectrum. FIG. 5 shows light emission spectra of the oxide phosphors according to Examples 1 and 2 and Comparative Example 1. FIG. 6 shows light emission spectra of the oxide phosphors according to Examples 3 and 4.

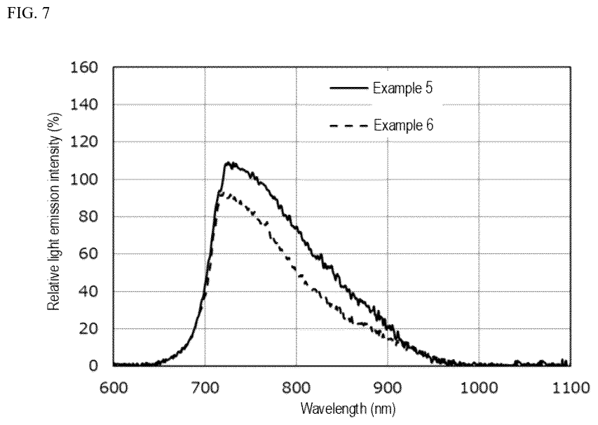

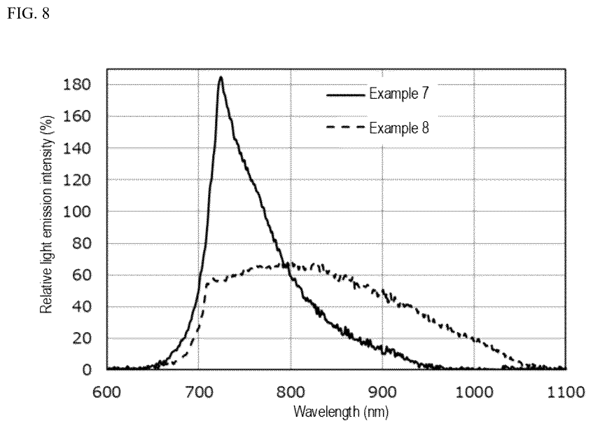

Each of the oxide phosphors according to Examples 5 to 8 had a composition represented by the formula (1) in which the element M² was Mg and the parameter r was 1 (r=1.0), and thus had a full width at half maximum of 50 nm or more and 130 nm or less in the light emission spectrum and a light emission peak wavelength of 680 nm or more and 730 nm or less in the light emission spectrum. FIG. 7 shows light emission spectra of the oxide phosphors according to Examples 5 and 6. FIG. 8 shows light emission spectra of the oxide phosphors according to Examples 7 and 8.

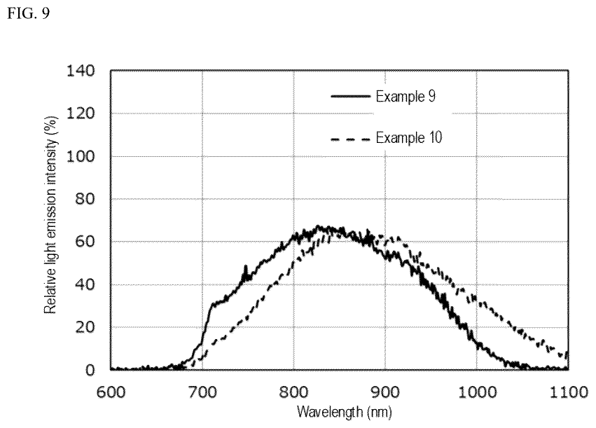

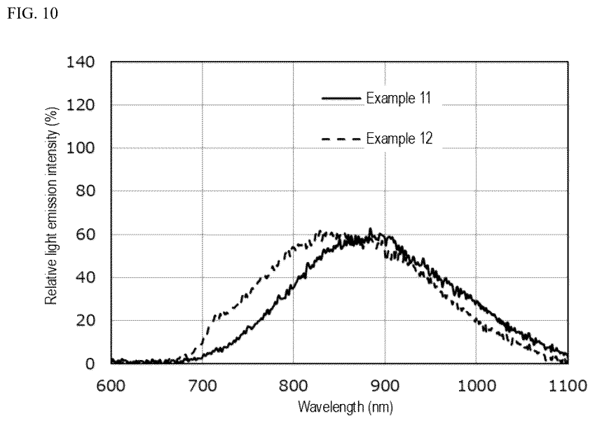

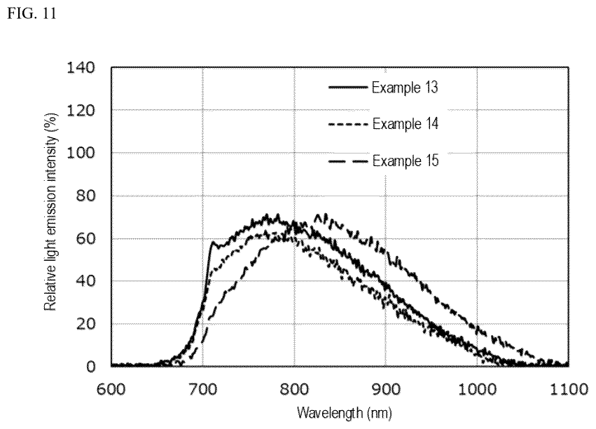

Each of the oxide phosphors according to Examples 9 to 15 had a composition represented by the formula (1) in which Zn was contained, either Mg was not contained as the element M² or the element M² was not contained, and the parameter w was 1.3 or more and 3.2 or less (1.3≤w≤3.2), and thus had a full width at half maximum of 190 nm or more and 250 nm or less in the light emission spectrum and a light emission peak wavelength of 750 nm or more and 900 nm or less in the light emission spectrum. FIG. 9 shows light emission spectra of the oxide phosphors according to Examples 9 and 10. FIG. 10 shows light emission spectra of the oxide phosphors according to Examples 11 and 12. FIG. 11 shows light emission spectra of the oxide phosphors according to Examples 13 to 15.

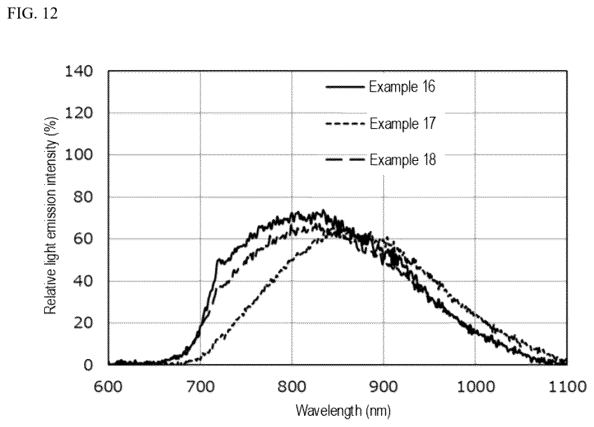

Each of the oxide phosphors according to Examples 16 to 18 had a composition represented by the formula (1) in which the parameters s and v satisfied s=0 and v=0, Zn and the element M² were not contained, and the element M⁴ was not contained, and thus had a full width at half maximum of 190 nm or more and 240 nm or less in the light emission spectrum and a light emission peak wavelength of 800 nm or more and 860 nm or less in the light emission spectrum. FIG. 12 shows light emission spectra of the oxide phosphors according to Examples 16 to 18.

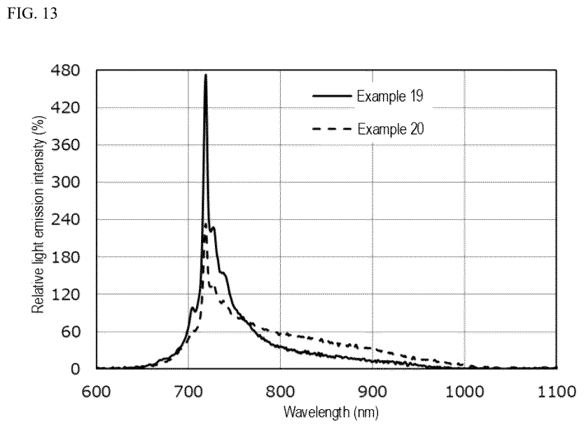

Each of the oxide phosphors according to Examples 19 and 20 had a composition represented by the formula (1) in which the element M⁴ was Si, and the parameters s and v satisfied s=0 and v=1.0, and thus had a full width at half maximum of 5 nm or more and 30 nm or less in the light emission spectrum and a light emission peak wavelength of 690 nm or more and 720 nm or less in the light emission spectrum. FIG. 13 shows light emission spectra of the oxide phosphors according to Examples 19 and 20.

The oxide phosphor according to Comparative Example 1 had an oxide composition in which part or all of Ga was not replaced with one or more elements selected from the group consisting of Zn, the element M², the element M³, Ge, and the element M⁴, and thus had a lower light emission intensity compared to those of the oxide phosphors according to Examples 1 to 20. The oxide phosphor according to Comparative Example 1 had a composition represented by the formula (a).

Embodiments according to the present disclosure include the following oxide phosphor and light emitting device.

The oxide phosphor according to the present disclosure can be used in light emitting devices for medical use to obtain information inside living bodies, light emitting devices to be mounted on small mobile devices such as smartphones and smartwatches to manage physical conditions, light emitting devices used in medical devices, light emitting devices for analyzers to non-destructively measure the internal information of agricultural products such as fruits, vegetables, rice, food, and pharmaceutical products, light emitting devices for plant cultivation to affect the photoreceptors of plants, and light emitting devices for reflection spectroscopic measuring devices used for measuring film thickness or the like.

What is claimed is:

1. An oxide phosphor, having a composition represented by the following formula (1):
(Li_{1-q}M¹_{q})₂(Zn₁₋ᵣM²ᵣ)ₛ(Ga₁₋ₜM³ₜ)ᵤ(Ge₁₋ᵥM⁴ᵥ)_{w}Oₓ:Cr_{y},M⁵_{z} (1),
wherein M¹ represents at least one element selected from the group consisting of Na, K, Rb, and Cs; M² represents at least one element selected from the group consisting of Mg, Ca, Sr, and Ba; M³ represents at least one element selected from the group consisting of Al, Sc, and In; M⁴ represents at least one element selected from the group consisting of Si, Ti, Zr, Sn, and Hf; M⁵ represents at least one element selected from the group consisting of Ni, Ce, Eu, Fe, Mn, Nd, Tm, Ho, Er, and Yb; q, r, s, t, u, v, w, and x satisfy 0≤q≤0.5, 0≤r≤1.0, 0≤s≤4.0, 0≤t≤1.0, 5≤u≤10, 0≤v≤1.0, 0.5≤w≤5.0, and 10≤x≤30; a molar ratio of Li is 2 or a total molar ratio of Li and M¹ is 2; y and z satisfy 0.02≤y≤0.5, 0≤z≤0.3, and y>z.

2. The oxide phosphor according to claim 1, wherein in the formula (1), y satisfies 0.02<y≤0.2.

3. The oxide phosphor according to claim 1, wherein in the formula (1), y satisfies 0.025≤y≤0.18.

4. The oxide phosphor according to claim 1, wherein in the formula (1), s satisfies 1.0≤s≤3.5.

5. The oxide phosphor according to claim 1, wherein in the formula (1), r and w satisfy r=0 and 0.8≤w≤3.0.

6. The oxide phosphor according to claim 5, wherein the oxide phosphor has a full width at half maximum in a range of 40 nm or more and 250 nm or less in a light emission spectrum.

7. The oxide phosphor according to claim 5, wherein the oxide phosphor has a light emission peak wavelength in a range of 700 nm or more and 900 nm or less in a light emission spectrum.

8. The oxide phosphor according to claim 1, wherein in the formula (1), w satisfies 1.3≤w≤3.2.

9. The oxide phosphor according to claim 8, wherein the oxide phosphor has a full width at half maximum in a range of 190 nm or more and 250 nm or less in a light emission spectrum.

10. The oxide phosphor according to claim 8, wherein the oxide phosphor has a light emission peak wavelength in a range of 750 nm or more and 900 nm or less in a light emission spectrum.

11. The oxide phosphor according to claim 1, wherein in the formula (1), s and v satisfy s=0 and v=0.

12. The oxide phosphor according to claim 11, wherein the oxide phosphor has a full width at half maximum in a range of 190 nm or more and 240 nm or less in a light emission spectrum.

13. The oxide phosphor according to claim 11, wherein the oxide phosphor has a light emission peak wavelength in a range of 800 nm or more and 860 nm or less in a light emission spectrum.

14. The oxide phosphor according to claim 1, wherein in the formula (1), M⁴ is Si, and s and v satisfy s=0 and v=1.0.

15. The oxide phosphor according to claim 14, wherein the oxide phosphor has a full width at half maximum that is 30 nm or less in a light emission spectrum.

16. The oxide phosphor according to claim 14, wherein the oxide phosphor has a light emission peak wavelength in a range of 690 nm or more and 720 nm or less in a light emission spectrum.

17. The oxide phosphor according to claim 1, wherein in the formula (1), M² is Mg, and r satisfies r=1.0.

18. The oxide phosphor according to claim 17, wherein the oxide phosphor has a full width at half maximum in a range of 50 nm or more and 130 nm or less in a light emission spectrum.

19. The oxide phosphor according to claim 17, wherein the oxide phosphor has a light emission peak wavelength in a range of 680 nm or more and 730 nm or less in a light emission spectrum.

20. Alight emitting device comprising:
the oxide phosphor according to any one of claim 1; and
a light emitting element configured to emit light having a light emission peak wavelength in a range of 365 nm or more and 650 nm or less and to irradiate the oxide phosphor with the light.
